(19) United States
(12) Patent Application Publication
(10) Pub. No.: US 2025/0362607 A1
(43) Pub. Date: Nov. 27, 2025

(54) DOSE REDUCTION BOTTOM ANTI-REFLECTIVE COATING FOR METALLIC PHOTORESIST

(71) Applicant: Taiwan Semiconductor Manufacturing Co., Ltd., Hsinchu (TW)

(72) Inventors: Yen-Yu KUO, Hsinchu (TW); An-Ren ZI, Hsinchu (TW); Chen-Yu LIU, Hsinchu (TW); Ching-Yu CHANG, Hsinchu (TW); Chin-Hsiang LIN, Hsinchu (TW)

(21) Appl. No.: 19/292,479

(22) Filed: Aug. 6, 2025

Related U.S. Application Data
(63) Continuation of application No. 18/361,298, filed on Jul. 28, 2023.
(60) Provisional application No. 63/493,236, filed on Mar. 30, 2023.

(51) Int. Cl. G03F 7/09; C09D 125/06; C09D 133/12; G03F 7/004; H01L 21/033

(52) U.S. Cl. CPC G03F 7/091; C09D 125/06; C09D 133/12; G03F 7/0044; H01L 21/033

(57) ABSTRACT

A method of forming semiconductor device includes depositing a coating layer over a substrate, forming a photoresist layer over the coating layer, exposing the photoresist layer to actinic radiation, and developing the photoresist layer to form a patterned photoresist layer. The coating layer includes a polymer containing a first unit having a pendant hydrogen donor group capable of producing a hydrogen radical upon exposure to the actinic radiation or heat, and a second unit having a pendant water donor group capable of producing water upon exposure to the actinic radiation or heat.

### PRIORITY CLAIM AND CROSS-REFERENCE

This application is a Continuation Application of U.S. application Ser. No. 18/361,298, filed Jul. 28, 2023, which claims the benefit of U.S. Provisional Patent Application No. 63/493,236, filed Mar. 30, 2023, which are incorporated by reference herein in their entireties.

### BACKGROUND

Semiconductor devices are used in a variety of electronic applications, such as personal computers, cell phones, digital cameras, and other electronic equipment. Semiconductor devices are fabricated by sequentially depositing dielectric layers, conductive layers, and semiconductor layers over a semiconductor substrate, and patterning the various material layers using photolithography. In a photolithography process, a photoresist is deposited over a substrate and is exposed to a radiation such as extreme ultraviolet (EUV) ray. The radiation exposure causes a chemical reaction in the exposed areas of the photoresist and creates a latent image corresponding to the mask pattern in the photoresist. The photoresist is next developed in a developer to remove either the exposed portions of the photoresist for a positive photoresist or the unexposed portions of the photoresist for a negative photoresist. The patterned photoresist is then used as an etch mask in subsequent etching processes in forming integrated circuits (ICs). Advancement in lithography is generally desirable to meet the demand of the continued semiconductor miniaturization.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of a method for fabricating a semiconductor device, in accordance with some embodiments of the disclosure.

FIGS. 2A-2H are cross-sectional views of a semiconductor device fabricated using the method of FIG. 1, in accordance with some embodiments of the disclosure.

FIG. 3A illustrates a first exemplary polymer in a middle material layer, in accordance with some embodiments of the disclosure.

FIG. 3B illustrate a reaction of a hydrogen donor group undergoes when exposed to radiation, in accordance with some embodiments of the disclosure.

FIG. 3C illustrate a reaction of a water donor group undergoes when exposed to radiation, in accordance with some embodiments of the disclosure.

FIG. 4 illustrates a second exemplary polymer in a middle material layer, in accordance with some embodiments of the disclosure.

FIG. 5 illustrate a first polymer, a second polymer and a third polymer in a middle material layer, in accordance with some embodiments of the disclosure.

FIG. 6 illustrates an organometallic resist compound, in accordance with some embodiments of the disclosure.

FIGS. 7A-7D illustrate a reaction of the organometallic resist compound of FIG. 6 undergoes when exposed to radiation, in accordance with some embodiments of the disclosure.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. System may be otherwise oriented (rotated 90 degrees or at other orientations) and the spatially relative descriptors used herein may likewise be interpreted accordingly.

When describing the compounds, compositions, methods and processes of the present disclosure, the following terms have the following meanings, unless otherwise indicated.

As described herein, the compounds disclosed herein may optionally be substituted with one or more substituents, such as illustrated generally below, or as exemplified by particular classes, subclasses, and species of the present disclosure. It will be appreciated that the phrase “optionally substituted” is used interchangeably with the phrase “substituted or unsubstituted”. In general, the term “substituted” whether proceeded by the term “optionally” or not, refers to the replacement of one or more hydrogen radicals in a given structure with the radical of a specified substituent. Unless otherwise indicated, an optionally substituted group may have a substituent at each substitutable position of the group. When more than one position in a given structure can be substituted with more than one substituent selected from a specified group, the substituent may be either the same or different at each position.

As used herein, the term “polymer” generally refers to a molecule composed of repeating structural units connected by covalent chemical bonds and characterized by a substantial number of repeating units (e.g., equal to or greater than 20 repeating units and often equal to or greater than 100 repeating units and often equal to or greater than 200 repeating units) and a number average molecular weight greater than or equal to 5,000 Daltons (Da) or 5 kDa, such as greater than or equal to 10 kDa, 15 kDa, 20 kDa, 30 kDa, 40 kDa, 50 kDa, or 100 kDa. Polymers are commonly the polymerization product of one or more monomer precursors. The term polymer includes homopolymers, i.e., polymers consisting of repeating units of a single monomer. The term polymer also includes copolymers which are formed when two or more different types of monomers are linked in the same polymer. Copolymers may comprise two or more monomer subunits, and include random, block, alternating, segmented, grafted, tapered and other copolymers. The term “crosslinked polymers” generally refers to polymers having one or multiple links between at least two polymer chains, which can result from multivalent monomers forming crosslinking sites upon polymerization.

As used herein, the term “group” may refer to a functional group of a chemical compound. Groups of the present compounds refer to an atom or a collection of atoms that are a part of the compound. Groups of the present disclosure may be attached to other atoms of the compound via one or more covalent bonds. Groups may also be characterized with respect to their valence state. The present disclosure includes groups characterized as monovalent, divalent, trivalent, etc. valence states.

As used herein, a broken line in a chemical structure can be used to indicate a bond to the rest of the molecule. For example, [symbol] in

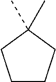

in is used to designate the 1-position as the point of attachment of 1-methylcyclopentate to the rest of the molecule. Alternatively,

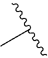

in, e.g.,

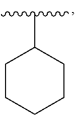 [SMILES: *C1CCCCC1]

can be used to indicate that the given moiety, the cyclohexyl moiety in this example, is attached to a molecule via the bond that is “capped” with the wavy line.

As used herein, a “linker” refers to a contiguous chain of at least one atom, such as carbon, oxygen, nitrogen, sulfur, phosphorous, and combinations thereof, which connects a portion of a molecule to another portion of the same molecule or to a different molecule, moiety or solid support (e.g., microparticle). Linkers may connect the molecule via a covalent bond or other means, such as ionic or hydrogen bond interactions. In some embodiments, the linker is a heteroatomic linker (e.g., comprising 1-10 Si, N, O, P, or S atoms), a heteroalkylene (e.g., comprising 1-10 Si, N, O, P, or S atoms and an alkylene chain) or an alkylene linker (e.g., comprising 1-12 carbon atoms). In some embodiments, the linker may contain an ether (—O—), ester (—OC(═O)—), or carbonate (—OC(═O)O—) linkage.

“Hydroxy” or “hydroxyl” refers to the —OH group.

“Aromatic” or “aromatic group” as used herein refers to a major group of unsaturated cyclic hydrocarbons containing one or more rings. An aromatic group may contain carbon (C), nitrogen (N), oxygen (O), sulfur(S), boron (B), or any combination thereof. At least some carbon is included. Aromatic includes both aryl and heteroaryl rings.

“Aliphatic” or “aliphatic group” as used herein means a straight-chain or branched C₁₋₁₂ hydrocarbon chain that is completely saturated or that contains one or more units of unsaturation, or a monocyclic C₃₋₈ hydrocarbon or bicyclic C₈₋₁₂ hydrocarbon that is completely saturated or that contains one or more units of unsaturation, but which is not aromatic (also referred to herein as “cycloalkyl”), that has a single point of attachment to the rest of the molecule where in any individual ring in said bicyclic ring system has 3-7 members. For example, suitable aliphatic groups include, but are not limited to, linear or branched alkyl, alkenyl, alkynyl groups and hybrids thereof such as (cycloalkyl)alkyl, (cycloalkenyl)alkyl or (cycloalkyl)alkenyl.

“Alkyl” refers to a straight or branched hydrocarbon chain group consisting solely of carbon and hydrogen atoms, containing no unsaturation, having from one to twelve carbon atoms (C₁-C₁₂ alkyl), one to eight carbon atoms (C₁-C₈ alkyl) or one to six carbon atoms (C₁-C₆ alkyl), and which is attached to the rest of the molecule by a single bond, e.g., methyl, ethyl, n-propyl, 1-methylethyl (iso-propyl), n-butyl, n-pentyl, 1,1-dimethylethyl (t-butyl), 3-methylhexyl, 2-methylhexyl, and the like. Unless stated otherwise specifically in the specification, alkyl groups are optionally substituted.

“Alkylene” or “alkylene chain” refers to a straight or branched divalent hydrocarbon chain linking the rest of the molecule to a radical group, consisting solely of carbon and hydrogen, containing no unsaturation, and having from one to twelve carbon atoms, e.g., methylene, ethylene, propylene, n-butylene, and the like. The alkylene chain is attached to the rest of the molecule through a single bond and to the radical group through a single bond. The points of attachment of the alkylene chain to the rest of the molecule and to the radical group can be through one carbon or any two carbons within the chain. Unless stated otherwise specifically in the specification, alkylene is optionally substituted.

“Alkenylene” or “alkenylene chain” refers to a straight or branched divalent hydrocarbon chain linking the rest of the molecule to a radical group, consisting solely of carbon and hydrogen, containing at least one carbon-carbon double bond and having from two to twelve carbon atoms, e.g., ethenylene, propenylene, n-butenylene, and the like. The alkenylene chain is attached to the rest of the molecule through a single bond and to the radical group through a double bond or a single bond. The points of attachment of the alkenylene chain to the rest of the molecule and to the radical group can be through one carbon or any two carbons within the chain. Unless stated otherwise specifically in the specification, alkenylene is optionally substituted.

“Alkynylene” or “alkynylene chain” refers to a straight or branched divalent hydrocarbon chain linking the rest of the molecule to a radical group, consisting solely of carbon and hydrogen, containing at least one carbon-carbon triple bond and having from two to twelve carbon atoms, e.g., ethynylene, propynylene, n-butynylene, and the like. The alkynylene chain is attached to the rest of the molecule through a single bond and to the radical group through a double bond or a single bond. The points of attachment of the alkynylene chain to the rest of the molecule and to the radical group can be through one carbon or any two carbons within the chain. Unless stated otherwise specifically in the specification, alkynylene is optionally substituted.

“Alkoxy” refers to a group of the formula —ORₐ where Rₐ is an alkyl group as defined above containing one to twelve carbon atoms. Unless stated otherwise specifically in the specification, an alkoxy group is optionally substituted.

“Cycloalkyl” refers to a stable non-aromatic monocyclic or polycyclic carbocyclic ring, which may include fused or bridged ring systems, having from three to fifteen carbon atoms, preferably having from three to ten carbon atoms, and which is saturated or unsaturated and attached to the rest of the molecule by a single bond. Monocyclic cyclocalkyls include, for example, cyclopropyl, cyclobutyl, cyclopentyl, cyclohexyl, cycloheptyl, and cyclooctyl. Polycyclic cycloalkyls include, for example, adamantyl, norbornyl, decalinyl, 7,7-dimethyl-bicyclo-[2.2.1]heptanyl, and the like. Unless stated otherwise specifically in the specification, a cycloalkyl group is optionally substituted.

“Heteroalkyl” refers to an alkyl group, as defined above, comprising at least one heteroatom (e.g., N, O, P or S) within the alkyl group or at a terminus of the alkyl group. In some embodiments, the heteroatom is within the alkyl group (i.e., the heteroalkyl comprises at least one carbon-[heteroatom]ₓ-carbon bond, where x is 1, 2 or 3). In other embodiments, the heteroatom is at a terminus of the alkyl group and thus serves to join the alkyl group to the remainder of the molecule (e.g., M1-H-A, where M1 is a portion of the molecule, H is a heteroatom and A is an alkyl group). Unless stated otherwise specifically in the specification, a heteroalkyl group is optionally substituted. Exemplary heteroalkyl groups include ethylene oxide (e.g., polyethylene oxide), optionally including phosphorous-oxygen bonds, such as phosphodiester bonds.

“Heteroalkylene” refers to an alkylene group, as defined above, comprising at least one heteroatom (e.g., N, O, P or S) within the alkylene chain or at a terminus of the alkylene chain. In some embodiments, the heteroatom is within the alkylene chain (i.e., the heteroalkylene comprises at least one carbon-[heteroatom]-carbon bond, where x is 1, 2 or 3). In other embodiments, the heteroatom is at a terminus of the alkylene and thus serves to join the alkylene to the remainder of the molecule (e.g., M1-H-A-M2, where M1 and M2 are portions of the molecule, H is a heteroatom and A is an alkylene). Unless stated otherwise specifically in the specification, a heteroalkylene group is optionally substituted.

“Heteroalkenylene” is a heteroalkylene, as defined above, comprising at least one carbon-carbon double bond. Unless stated otherwise specifically in the specification, a heteroalkenylene group is optionally substituted.

“Heteroalkynylene” is a heteroalkylene comprising at least one carbon-carbon triple bond. Unless stated otherwise specifically in the specification, a heteroalkynylene group is optionally substituted.

“Heteroatomic” in reference to a “heteroatomic linker” refers to a linker group consisting of one or more heteroatoms. Exemplary heteroatomic linkers include single atoms selected from the group consisting of O, N, P and S, and multiple heteroatoms for example a linker having the formula —P(O⁻)(═O)O— or —OP(O⁻)(═O)O— and multimers and combinations thereof.

“Aryl” refers to a ring system comprising at least one carbocyclic aromatic ring. In some embodiments, an aryl comprises from 6 to 18 carbon atoms. The aryl ring may be a monocyclic, bicyclic, tricyclic or tetracyclic ring system, which may include fused or bridged ring systems. Aryls include, but are not limited to, aryls derived from aceanthrylene, acenaphthylene, acephenanthrylene, anthracene, azulene, benzene, chrysene, fluoranthene, fluorene, as-indacene, s-indacene, indane, indene, naphthalene, phenalene, phenanthrene, pleiadene, pyrene, and triphenylene. Unless stated otherwise specifically in the specification, an aryl group is optionally substituted.

“Heteroaryl” refers to a 5- to 14-membered ring system comprising one to thirteen carbon atoms, one to six heteroatoms selected from the group consisting of nitrogen, oxygen and sulfur, and at least one aromatic ring. For purposes of certain embodiments of this disclosure, the heteroaryl radical may be a monocyclic, bicyclic, tricyclic or tetracyclic ring system, which may include fused or bridged ring systems; and the nitrogen, carbon or sulfur atoms in the heteroaryl radical may be optionally oxidized; the nitrogen atom may be optionally quaternized. Examples include, but are not limited to, azepinyl, acridinyl, benzimidazolyl, benzthiazolyl, benzindolyl, benzodioxolyl, benzofuranyl, benzooxazolyl, benzothiazolyl, benzothiadiazolyl, benzo[b][1,4] dioxepinyl, 1,4-benzodioxanyl, benzonaphthofuranyl, benzoxazolyl, benzodioxolyl, benzodioxinyl, benzopyranyl, benzopyranonyl, benzofuranyl, benzofuranonyl, benzothienyl (benzothiophenyl), benzotriazolyl, benzo[4,6]imidazo[1,2-a]pyridinyl, benzoxazolinonyl, benzimidazolthionyl, carbazolyl, cinnolinyl, dibenzofuranyl, dibenzothiophenyl, furanyl, furanonyl, isothiazolyl, imidazolyl, indazolyl, indolyl, indazolyl, isoindolyl, indolinyl, isoindolinyl, isoquinolyl, indolizinyl, isoxazolyl, naphthyridinyl, oxadiazolyl, 2-oxoazepinyl, oxazolyl, oxiranyl, 1-oxidopyridinyl, 1-oxidopyrimidinyl, 1-oxidopyrazinyl, 1-oxidopyridazinyl, 1-phenyl-1 H-pyrrolyl, phenazinyl, phenothiazinyl, phenoxazinyl, phthalazinyl, pteridinyl, pteridinonyl, purinyl, pyrrolyl, pyrazolyl, pyridinyl, pyridinonyl, pyrazinyl, pyrimidinyl, pryrimidinonyl, pyridazinyl, pyrrolyl, pyrido[2,3-d]pyrimidinonyl, quinazolinyl, quinazolinonyl, quinoxalinyl, quinoxalinonyl, quinolinyl, isoquinolinyl, tetrahydroquinolinyl, thiazolyl, thiadiazolyl, thieno[3,2-d]pyrimidin-4-onyl, thieno[2,3-d]pyrimidin-4-onyl, triazolyl, tetrazolyl, triazinyl, and thiophenyl (i.e., thienyl). Unless stated otherwise specifically in the specification, a heteroaryl group is optionally substituted.

“Heterocyclic” refers to a stable 3- to 18-membered aromatic or non-aromatic ring comprising one to twelve carbon atoms and from one to six heteroatoms selected from the group consisting of nitrogen, oxygen and sulfur. Unless stated otherwise specifically in the specification, the heterocyclic ring may be a monocyclic, bicyclic, tricyclic or tetracyclic ring system, which may include fused or bridged ring systems; and the nitrogen, carbon or sulfur atoms in the heterocyclic ring may be optionally oxidized; the nitrogen atom may be optionally quaternized; and the heterocyclic ring may be partially or fully saturated. Examples of aromatic heterocyclic rings are listed below in the definition of heteroaryls (i.e., heteroaryl being a subset of heterocyclic). Examples of non-aromatic heterocyclic rings include, but are not limited to, dioxolanyl, thienyl[1,3]dithianyl, decahydroisoquinolyl, imidazolinyl, imidazolidinyl, isothiazolidinyl, isoxazolidinyl, morpholinyl, octahydroindolyl, octahydroisoindolyl, 2-oxopiperazinyl, 2-oxopiperidinyl, 2-oxopyrrolidinyl, oxazolidinyl, piperidinyl, piperazinyl, 4-piperidonyl, pyrrolidinyl, pyrazolidinyl, pyrazolopyrimidinyl, quinuclidinyl, thiazolidinyl, tetrahydrofuryl, trioxanyl, trithianyl, triazinanyl, tetrahydropyranyl, thiomorpholinyl, thiamorpholinyl, 1-oxo-thiomorpholinyl, and 1,1-dioxo-thiomorpholinyl. Unless stated otherwise specifically in the specification, a heterocyclic group is optionally substituted.

The term “substituted” used herein means any of the above groups wherein at least one hydrogen atom (e.g., 1, 2, 3 or all hydrogen atoms) is replaced by a bond to a non-hydrogen atoms such as, but not limited to: a halogen atom such as F, Cl, Br, and I; an oxygen atom in groups such as hydroxyl groups, alkoxy groups, and ester groups; a sulfur atom in groups such as thiol groups, thioalkyl groups, sulfone groups, sulfonyl groups, and sulfoxide groups; a nitrogen atom in groups such as amines, amides, alkylamines, dialkylamines, arylamines, alkylarylamines, diarylamines, N-oxides, imides, and enamines; a silicon atom in groups such as trialkylsilyl groups, dialkylarylsilyl groups, alkyldiarylsilyl groups, and triarylsilyl groups; and other heteroatoms in various other groups. “Substituted” also means any of the above groups in which one or more hydrogen atoms are replaced by a higher-order bond (e.g., a double-or triple-bond) to a heteroatom such as oxygen in oxo, carbonyl, carboxyl, and ester groups; and nitrogen in groups such as imines, oximes, hydrazones, and nitriles. For example, “substituted” includes any of the above groups in which one or more hydrogen atoms are replaced with —NR_{g}Rₕ, —NR_{g}C(═O)Rₕ, —NR_{g}C(═O)NR_{g}Rₕ, —NR_{g}C(═O)ORₕ, —NR_{g}SO₂Rₕ, —OC(═O)NR_{g}Rₕ, —OR_{g}, —SR_{g}, —SOR_{g}, —SO₂R_{g}, —OSO₂R_{g}, —SO₂OR_{g}, =NSO₂R_{g}, and —SO₂NR_{g}Rₕ. “Substituted” also means any of the above groups in which one or more hydrogen atoms are replaced with —C(═O)R_{g}, —C(═O)OR_{g}, —C(═O)NR_{g}Rₕ, —CH₂SO₂R_{g}, and —CH₂SO₂NR_{g}Rₕ. In the foregoing, R_{g} and Rₕ are the same or different and independently hydrogen, alkyl, alkoxy, alkylamino, thioalkyl, aryl, aralkyl, cycloalkyl, cycloalkylalkyl, haloalkyl, heterocyclyl, N-heterocyclyl, heterocyclylalkyl, heteroaryl, N-heteroaryl and/or heteroarylalkyl. “Substituted” further means any of the above groups in which one or more hydrogen atoms are replaced by a bond to an amino, cyano, hydroxyl, imino, nitro, oxo, thioxo, halo, alkyl, alkoxy, alkylamino, thioalkyl, aryl, aralkyl, cycloalkyl, cycloalkylalkyl, haloalkyl, heterocyclyl, N-heterocyclyl, heterocyclylalkyl, heteroaryl, N-heteroaryl and/or heteroarylalkyl group. In addition, each of the foregoing substituents may also be optionally substituted with one or more of the above substituents.

IC fabrication uses one or more photolithography processes to transfer geometric patterns to a film or substrate. Geometric shapes and patterns on a semiconductor make up the complex structures that allow the dopants, electrical properties and wires to complete a circuit and fulfill a technological purpose. In a photolithography process, a photoresist is applied as a thin film to a substrate, and subsequently exposed to one or more types of radiation or light through a photomask. The photomask contains clear and opaque features that define a pattern which is to be created in the photoresist layer. Areas in the photoresist exposed to light transmitted through the photomask are made either soluble or insoluble in a specific type of solution known as a developer. In the case when the exposed regions are soluble, a positive image of the photomask is produced in the photoresist and this type of photoresist is called a positive photoresist. On the other hand, if the unexposed areas are dissolved by the developer, a negative image results in the photoresist and this type of photoresist is called a negative photoresist. The developer removes the more soluble areas, leaving the patterned photoresist in place. The resist pattern is then used as an etch mask in subsequent etching processes, transferring the pattern to an underlying material layer, thereby replicating the mask pattern in the underlying material layer. Alternatively, the resist pattern is then used as an ion implantation mask in subsequent ion implantation processes applied to the underlying material layer, such as an epitaxial semiconductor layer.

As the semiconductor device sizes continue to shrink, for example, below 20 nanometer nodes, traditional lithography technologies have optical restrictions, which leads to resolution issues and may not achieve the desired lithography performance. In comparison, extreme ultraviolet (EUV) lithography using EUV radiation around 13.5 nm can achieve much smaller device sizes. However, as the decrease in wavelength causes decrease in photo flux, conventional polymer-based photoresists, which suffer from low absorption efficiency to EUV radiation, are no longer suitable for EUV lithography as they require longer exposure time, resulting in reduced throughput and leading to various patterning issues, such as increased line width roughness (LWR) and critical dimension (CD) non-uniformity.

Metallic resists containing metals with high EUV photo absorption have been developed to improve the resist sensitivity to the EUV radiation, thereby lowering exposure doses required for defining the pattern in the photoresist layer. Organometallic compounds having photo cleavable organic ligands bonded to the metals are used as precursors for EUV photoresist. These photo cleavable ligands are cleaved when exposed to radiation to generate radicals. Radicals generated from the metal core-ligand bond cleavage initiate and trigger polymerization, during which the metal core radical is first react with embodiment water to form a metal hydroxide, and the subsequent condensation of metal hydroxides forms the metal-oxy clusters.

Embodiments of present disclosure provide bottom anti-reflective coating compositions for improving integrity of the photoresist pattern and reduce exposure dose of organometallic resist compound. The coating compositions include polymers containing hydrogen donor groups and water donor groups. The hydrogen donor groups generate hydrogen radicals when exposed to radiation. The hydrogen radicals diffuse into the photoresist layer and stabilize the resist intermediates, which in turn facilitate the cleavage of the metal core-ligand bond. The hydrogen donor groups thus help to increase crosslinking efficiency and allow the reduction of radiation energy and doses. The water donor groups generate water when exposed to radiation. The water diffuses into the photoresist layer and reacts with the metal core radical to form metal hydroxide The water donor group thus helps to improve the hydrolysis of the organometallic resist compound, which in turn helps to increase the crosslinking density of the photoresist. Embodiments of the present disclosure allow forming photoresist patterns with improved line width roughness and critical dimension uniformity. Embodiments of the present disclosure also allow reduced exposure dose and increase the manufacturing yield of semiconductor devices.

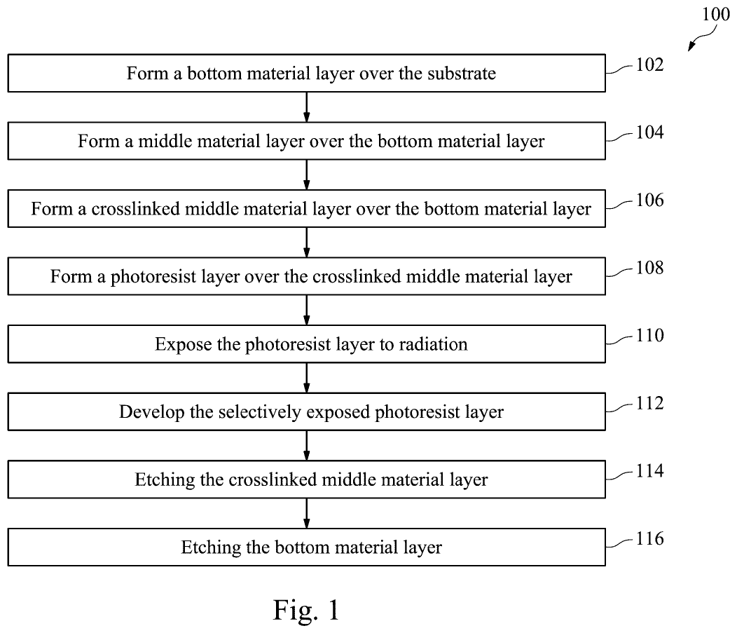

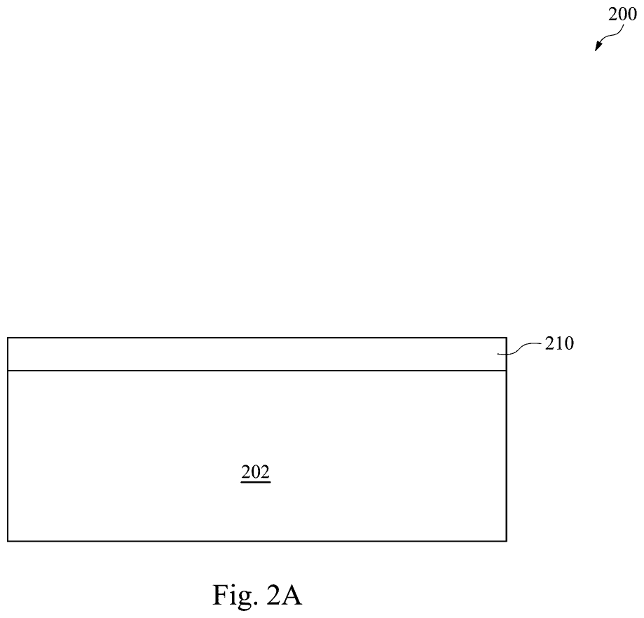

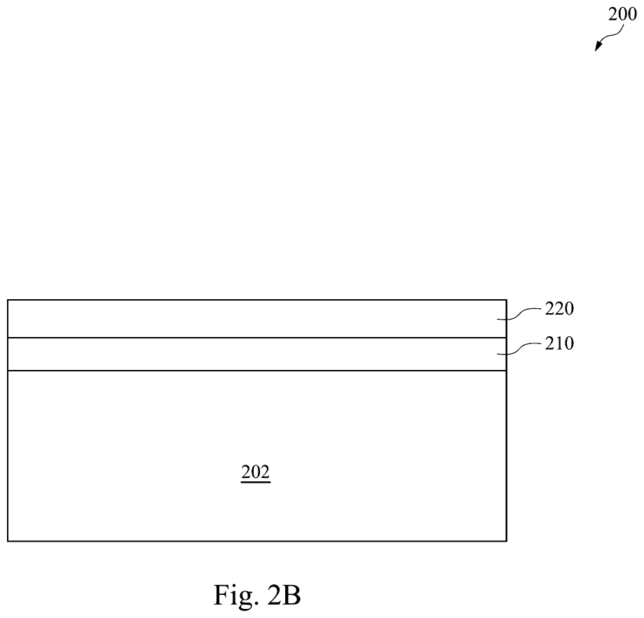

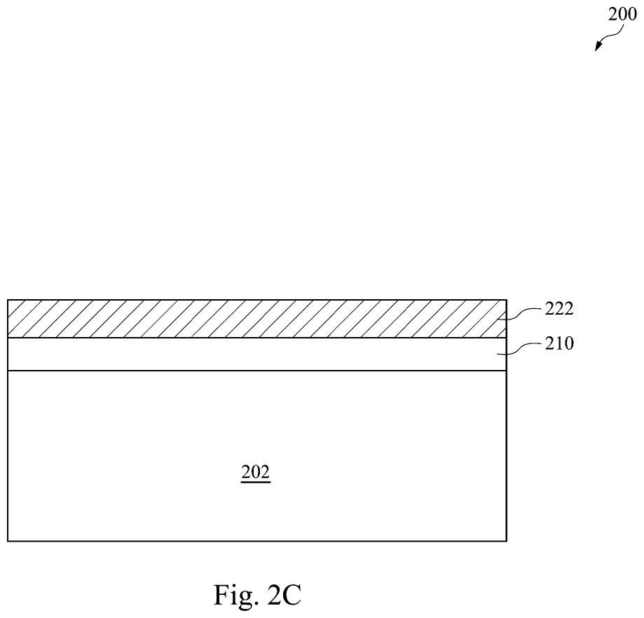

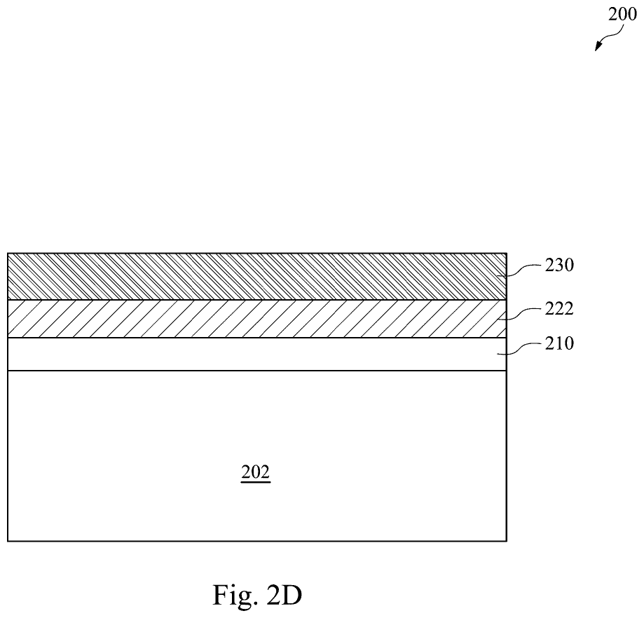

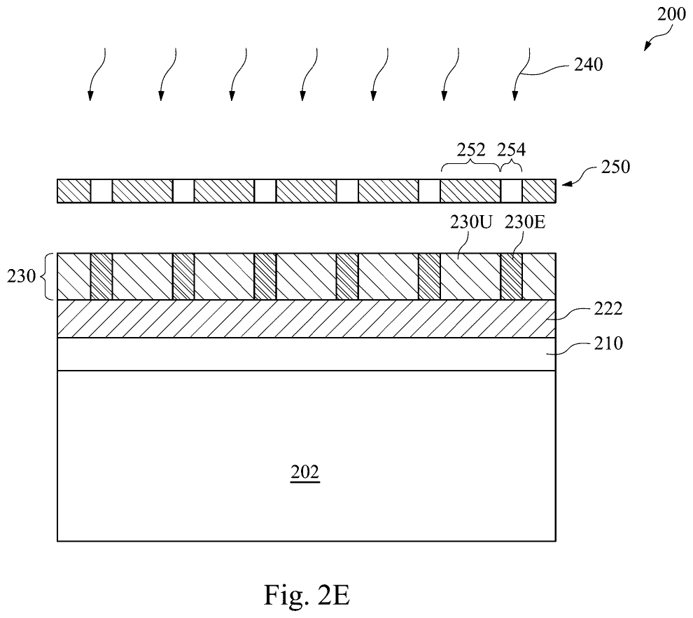

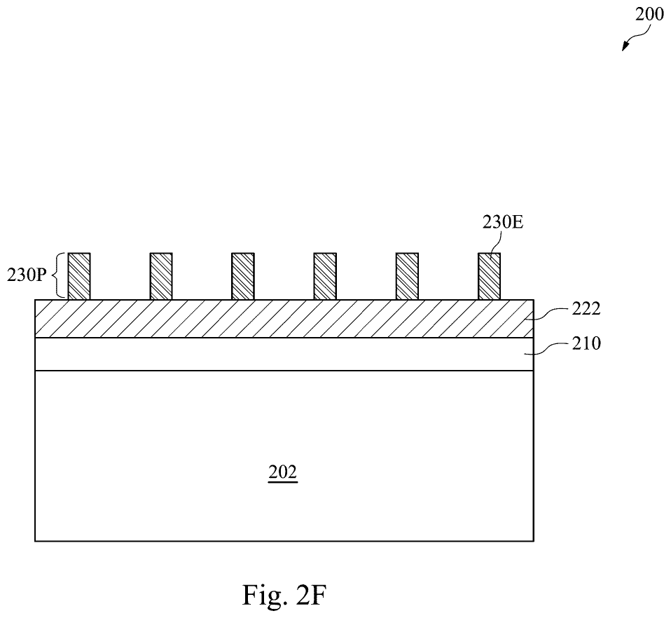

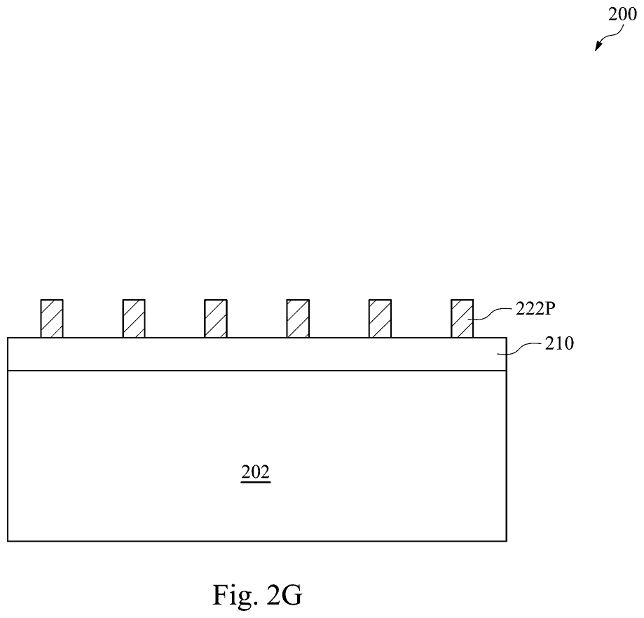

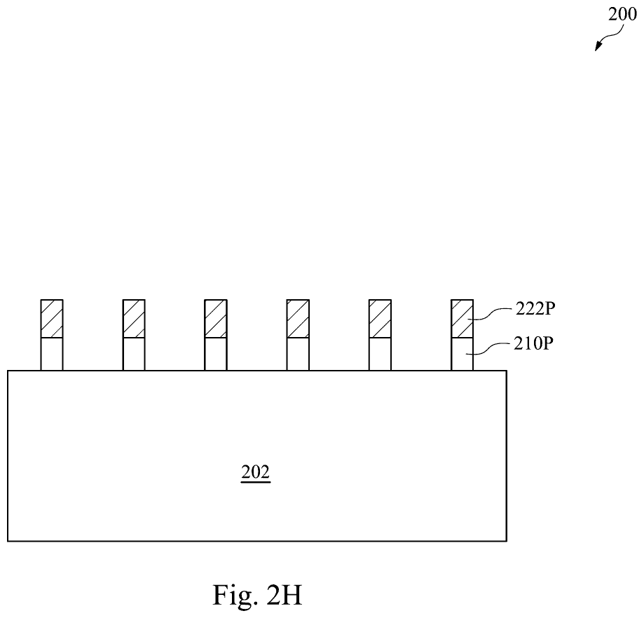

FIG. 1 is a flowchart of a method 100 of forming a semiconductor device, in accordance with some embodiments of the present disclosure. FIGS. 2A-2H are cross-sectional views of a semiconductor device 200 fabricated according to one or more steps of the method 100. It is understood that additional steps can be provided before, during, and after the method 100, and some of the steps described below can be replaced or eliminated, for additional embodiments of the method. It is further understood that additional features can be added in the semiconductor device 200, and some of the features described below can be replaced or eliminated, for additional embodiments of the semiconductor device 200.

The semiconductor device 200 may be an intermediate device fabricated during processing of an integrated circuit, or portion thereof, that may comprise static random access memory (SRAM) and/or other logic circuits, passive components such as resistors, capacitors, and inductors, and active components such as P-channel field effect transistors (PFET), N-channel FET (NFET), metal-oxide semiconductor field effect transistors (MOSFET), complementary metal-oxide semiconductor (CMOS) transistors, bipolar transistors, high voltage transistors, high frequency transistors, other memory cells, and combinations thereof. The semiconductor device 200 includes a plurality of semiconductor devices (e.g., transistors), which may be interconnected.

Referring to FIGS. 1 and 2A, the method 100 includes an operation 102, in which a bottom material layer 210 is deposited over a substrate 202, in accordance with some embodiments. FIG. 2A is a cross-sectional view of a semiconductor device 200 after depositing the bottom material layer 210 over the substrate 202. The bottom material layer 210 may be a first layer of a trilayer patterning stack.

In some embodiments, the substrate 202 is a bulk semiconductor substrate including one or more semiconductor materials. In some embodiments, the substrate 202 includes silicon, silicon germanium, carbon doped silicon (Si:C), silicon germanium carbide, or other suitable semiconductor materials. In some embodiments, the substrate 202 is composed entirely of silicon.

In some embodiments, the substrate 202 includes one or more epitaxial layers formed on a top surface of a bulk semiconductor substrate. In some embodiments, the one or more epitaxial layers introduce strains in the substrate 202 for performance enhancement. For example, the epitaxial layer includes a semiconductor material different from that of the bulk semiconductor substrate, such as a layer of silicon germanium overlying bulk silicon or a layer of silicon overlying bulk silicon germanium. In some embodiments, the epitaxial layer(s) incorporated in the substrate 202 are formed by selective epitaxial growth, such as, for example, metalorganic vapor phase epitaxy (MOVPE), molecular beam epitaxy (MBE), hydride vapor phase epitaxy (HVPE), liquid phase epitaxy (LPE), metal-organic molecular beam epitaxy (MOMBE), or combinations thereof.

In some embodiments, the substrate 202 is an active layer of a semiconductor-on-insulator (SOI) substrate. In some embodiments, the SOI substrate includes a semiconductor layer, such as a silicon layer formed on an insulator layer. In some embodiments, the insulator layer is a buried oxide (BOX) layer including silicon oxide or silicon germanium oxide. The insulator layer is provided on a handle substrate such as, for example, a silicon substrate. In some embodiments, the SOI substrate is formed using separation by implanted oxygen (SIMOX) or wafer bonding.

The substrate 202 may also include other material layers and other circuit patterns. In some embodiments, the substrate 202 includes various doped regions formed by a process such as ion implantation and/or diffusion. The doped regions are doped with p-type and/or n-type dopants. The term “p-type” refers to the addition of impurities to an intrinsic semiconductor that creates deficiencies of valence electrons. Examples of p-type dopants, i.e., impurities, include, but are not limited to, boron, boron difluoride, gallium, and indium. The term “n-type” refers to the addition of impurities that contributes free electrons to an intrinsic semiconductor. Examples of n-type dopants, i.e., impurities, include, but are not limited to, antimony, arsenic, and phosphorous. In other embodiments, the substrate 202 may further include one or more material layers to be patterned (by etching to remove or ion implantation to introduce dopants), such as a dielectric layer to be patterned to form trenches for conductive lines or holes for contacts or vias; a gate material stack to be patterned to form gates; or a semiconductor material to be patterned to form isolation trenches. For example, a material layer to be patterned is a semiconductor layer as a part of the substrate 202. In other embodiments, multiple semiconductor material layers, such as gallium arsenic (GaAs) and aluminum gallium arsenic (AlGaAs), are epitaxially grown on the substrate 202 and are patterned to form various devices, such as light-emitting diodes (LEDs). In some other embodiments, the substrate 202 includes fin active regions and three dimensional fin field-effect transistors (FinFETs) formed or to be formed thereon.

The bottom material layer 210 is deposited on the substrate 202. The bottom material layer 210 functions as a mask to protect the substrate 202 from etching or ion implantation. In some embodiments, the bottom material layer 210 also functions as a planarization layer to provide a planar surface upon which a middle material layer 220 (FIG. 2B) is formed. In some embodiments, the bottom material layer 210 includes an organic polymer free of silicon. For example, the bottom material layer 210 may include spin-on carbon, diamond-like carbon, polyarylene ether, or polyimide. In some embodiments, the bottom material layer 210 is formed by spin coating, spry coating, dip coating, or other suitable deposition processes. The bottom material layer 210 is formed to have a thickness sufficient to provide a planar surface and etching resistance. In some embodiments, the bottom material layer 210 may have a thickness ranging from about 50 nm to about 300 nm. If the thickness of the bottom material layer 210 is too small, the bottom material layer 210 is not able to provide a planar surface and sufficient etching resistance, in some instances. On the other hand, if the thickness of the bottom material layer 210 is too great, production costs are increased as a result of unnecessary consumption of material and increased processing time to pattern the bottom material layer 210, in some instances.

Referring to FIGS. 1 and 2B, the method 100 proceeds to operation 104, in which a middle material layer 220 is deposited over the bottom material layer 210, in accordance with some embodiments. FIG. 2B is a cross-sectional view of the semiconductor device 200 of FIG. 2A after depositing the middle material layer 220 over the bottom material layer 210. The middle material layer 220 may be a second layer of the trilayer patterning stack, and is also referred to as a photoresist under-layer.

The middle material layer 220 includes a material that provides etching selectivity from the bottom material layer 210. The middle material layer 220 thus functions as an etch mask to transfer a pattern to the bottom material layer 210. In some embodiments, the middle material layer 220 also functions as a bottom anti-reflective coating (BARC) layer. The BARC layer absorbs actinic radiation that passes through the photoresist layer, thereby preventing the actinic radiation from reflecting off the substrate 202 and exposing unintended portions of the photoresist layer. Thus, the BARC layer improves line width roughness and line edge roughness of the photoresist pattern formed thereon.

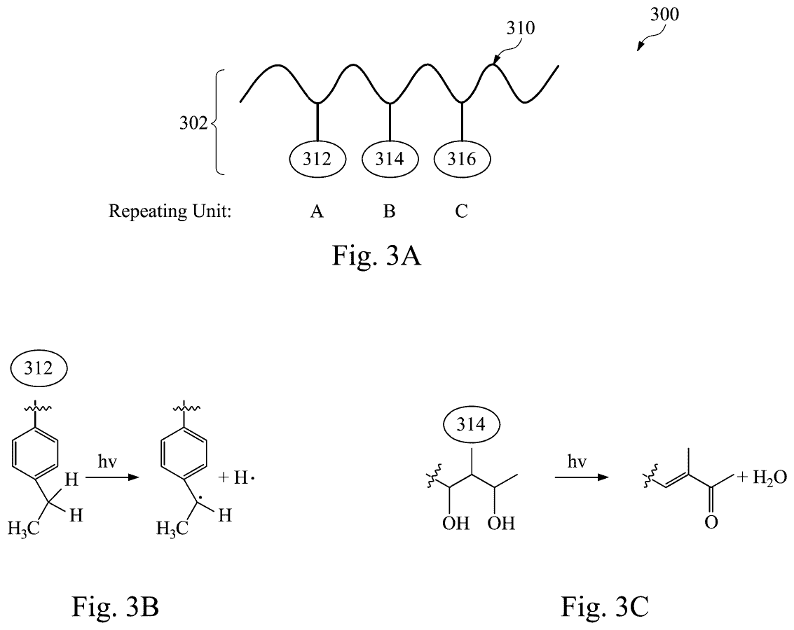

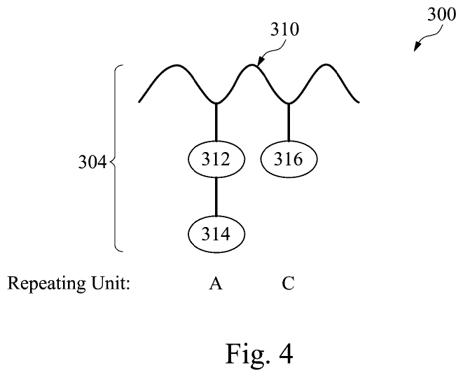

In some embodiments, the middle material layer 220 includes a coating composition comprising a polymer 300. The polymer 300 (FIG. 3A and FIG. 4) includes both hydrogen donor group 312 and water donor group 314 attached to a polymer backbone 310 for facilitating the metal core-ligand bond cleavage and condensation of metal hydroxide in the photoresist layer subsequently formed thereon. The term “pendant group” refers to a group attached to, but does not form a part of, a polymer backbone. In some embodiments, the polymer backbone 310 of the polymer 300 includes repeating units selected from the group consisting of acrylic esters, methacrylic esters, crotonic esters, vinyl esters, maleic diesters, fumaric diesters, itaconic diesters, (meth)acrylonitriles, (meth)acrylamides, styrenes, hydroxystyrenes, vinyl ethers, and combinations thereof. In some embodiments, the polymer 300 has a polymethylmethacrylate or polyhydroxystyrene backbone. In some embodiments, the polymer backbone 310 is a copolymer of polymethylmethacrylate and polyhydroxystyrene.

Specific structures that are utilized for repeating units of the polymer backbone 310 in some embodiments, include one or more of methyl acrylate, ethyl acrylate, n-propyl acrylate, isopropyl acrylate, n-butyl acrylate, isobutyl acrylate, tert-butyl acrylate, n-hexyl acrylate, 2-ethylhexyl acrylate, acetoxyethyl acrylate, phenyl acrylate, 2-hydroxyethyl acrylate, 2-methoxyethyl acrylate, 2-ethoxyethyl acrylate, 2-(2-methoxyethoxy)ethyl acrylate, cyclohexyl acrylate, benzyl acrylate, 2-alkyl-2-adamantyl (meth)acrylate or dialkyl(1-adamantyl)methyl (meth)acrylate, methyl methacrylate, ethyl methacrylate, n-propyl methacrylate, isopropyl methacrylate, n-butyl methacrylate, isobutyl methacrylate, tert-butyl methacrylate, n-hexyl methacrylate, 2-ethylhexyl methacrylate, acetoxyethyl methacrylate, phenyl methacrylate, 2-hydroxyethyl methacrylate, 2-methoxyethyl methacrylate, 2-ethoxyethyl methacrylate, 2-(2-methoxyethoxy)ethyl methacrylate, cyclohexyl methacrylate, benzyl methacrylate, 3-chloro-2-hydroxypropyl methacrylate, 3-acetoxy-2-hydroxypropyl methacrylate, 3-chloroacetoxy-2-hydroxypropyl methacrylate, butyl crotonate, hexyl crotonate, or the like. Examples of the vinyl esters include vinyl acetate, vinyl propionate, vinyl butylate, vinyl methoxyacetate, vinyl benzoate, dimethyl maleate, diethyl maleate, dibutyl maleate, dimethyl fumarate, diethyl fumarate, dibutyl fumarate, dimethyl itaconate, diethyl itaconate, dibutyl itaconate, acrylamide, methyl acrylamide, ethyl acrylamide, propyl acrylamide, n-butyl acrylamide, tert-butyl acrylamide, cyclohexyl acrylamide, 2-methoxyethyl acrylamide, dimethyl acrylamide, diethyl acrylamide, phenyl acrylamide, benzyl acrylamide, methacrylamide, methyl methacrylamide, ethyl methacrylamide, propyl methacrylamide, n-butyl methacrylamide, tert-butyl methacrylamide, cyclohexyl methacrylamide, 2-methoxyethyl methacrylamide, dimethyl methacrylamide, diethyl methacrylamide, phenyl methacrylamide, benzyl methacrylamide, methyl vinyl ether, butyl vinyl ether, hexyl vinyl ether, methoxyethyl vinyl ether, dimethylaminoethyl vinyl ether, or the like. Examples of styrenes include styrene, methyl styrene, dimethyl styrene, trimethyl styrene, ethyl styrene, isopropyl styrene, butyl styrene, methoxy styrene, butoxy styrene, acetoxy styrene, hydroxy styrene, chloro styrene, dichloro styrene, bromo styrene, vinyl methyl benzoate, a-methyl styrene, maleimide, vinylpyridine, vinylpyrrolidone, vinylcarbazole, combinations of these, or the like.

FIG. 3A illustrates a first exemplary polymer 300 (referred to as polymer 302) that can be used in the middle material layer 220, in accordance with some embodiments. Referring to FIG. 3A, the polymer 302 is copolymer made up of two or more repeating units. In some embodiments, the polymer 302 includes a first repeating unit A having a pendant hydrogen donor group 312, a second repeating unit B having a pendant water donor group 314, and a third repeating unit C having a pendant crosslinking group 316. The third repeating unit C having the pendant crosslinking group 316 is optional and may be omitted in some embodiments. If the third monomer unit C is omitted, the coating composition may include an crosslinking agent to form polymer networks in the middle material layer 220.

The hydrogen donor group 312 is capable of producing a hydrogen radical upon exposure to the actinic radiation or heat. In some embodiments, the hydrogen donor group 312 comprises a saturated or unsaturated hydrocarbon group. Upon exposure to light or heat, the photon energy or heat triggers the homolytic cleavage of a C—H bond in the hydrogen donor group 312 to generate a hydrogen radical (FIG. 3B). The hydrogen radical can diffuse into the photoresist layer and bind with a ligand radical that is cleaved from the organometallic resist compound during the exposure step to stabilize the intermediate of the organometallic compound. The hydrogen donor group 312 thus helps to facilitate the crosslinking of the organometallic resist compound and reduces the required EUV dose for exposure. In some embodiments, the hydrogen donor group 312 comprises a linear, branched or cyclic aliphatic group or an aromatic group. In some embodiments, the hydrogen donor group 312 is a linear or branched C₃-C₂₀ alkenyl group or a C₁-C₄ alkyl-substituted aryl group. In some embodiments, the aryl group is a phenyl group, a naphthalenyl group, a phenanthrenyl group, an anthracenyl group, a phenalenyl group, or a three-to five-membered ring. In some embodiments, the hydrogen donor group 312 is present in the polymer 302 in an amount ranging from about 1 wt. % to about 70 wt. % of the polymer 302. When the amount of the hydrogen donor group 312 is outside the disclosed ranges, there may not be an improvement in the dose reduction.

The water donor group 314 is capable of producing water upon exposure to the actinic radiation or heat. In some embodiments, the water donor group 314 is a dihydric or higher alcohol containing two or more hydroxyl groups. Upon exposure to light or heat, adjacent hydroxyl groups of a polyol undergo a condensation reaction to generate water (FIG. 3C). The water can diffuse into the photoresist layer to react with the metal core radical to form metal hydroxy. The water donor group 314 thus helps to facilitate the crosslinking of the organometallic resist compound and reduce the required EUV dose for exposure. In some embodiments, the water donor group 314 is a linear, branched or cyclic aliphatic group having two or more hydroxyl groups. In some embodiments, the water donor group 314 is present in the polymer 302 in an amount ranging from about 1 wt. % to about 70 wt. % of the polymer 302. When the amount of the water donor group 314 is outside the disclosed ranges, there may not be an improvement in the dose reduction.

The crosslinking group 316 is a thermal sensitive or a photo-sensitive group. In some embodiments, the crosslinking group 316 is operable to crosslink with another crosslinking group under heat to initiate the crosslinking reaction of the crosslinking group 316. The reaction of the crosslinking groups 316 bonds two polymer chains together to form polymer networks. The crosslinking improves the solvent resistance of the middle material layer 220, so that the middle material layer 220 will not be dissolved by the solvent used to form the photoresist layer. In some embodiments, the crosslinking group 316 is an aliphatic group having a functional group selected from the group consisting of an epoxy group, a hydroxide group, an azo group, an alkyl halide group, an imine group, an alkene group, an alkyne group, a peroxide group, a ketone group, an aldehyde group, an allene group, or a heterocyclic group. In some embodiments, the crosslinking group 316 is about 10 wt. % to about 70 wt. % of the polymer 302. If the amount of the crosslinking groups is less than about 10 wt. % the middle material layer may have insufficient solvent resistance to the photoresist solvent. If the amount of the crosslinking groups is greater than about 70 wt. % the polymer may lack sufficient solubility in the solvent.

In some embodiments, the hydrogen donor groups 312, the water donor groups 314, and the crosslinking groups 316 are bonded to the polymer backbones 310 by respective linkers selected from cyclic or noncyclic, saturated or unsaturated, substituted or unsubstituted, or branched or unbranched C₁-C₁₂ aliphatic or C₃-C₂₀ aromatic groups, for example, unsubstituted or halogen-substituted C₁-C₁₂ alkylene groups or C₂-C₁₂ alkylene groups interrupted by —S—, —P—, —P(O₂)—, —C(═O)S—, —C(═O)O—, —O—, —N—, —C(═O)N—, —SO₂O—, —SO₂S—, —SO—, —SO₂—, —C₆H₆—O—, —C₆H₆—O—C(═O)O—, or —C(═O)—.

In some embodiments, the polymer 302 has the following structure (I):

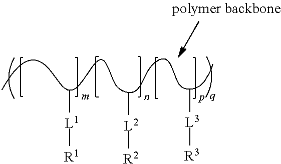

wherein:
L¹, L² and L³ are, at each occurrence, independently an optional alkylene, alkenylene, alkynylene, heteroalkylene, heteroalkenylene, heteroalkynylene, cycloalkylene, heterocycloalkylene, arylene, or heteroarylene linker;
R¹ is, at each occurrence, a hydrogen donor group;
R² is, at each occurrence, a water donor group;
R³ is, at each occurrence, a crosslinking group;
m, n and q are independently an integer of one or greater; and
p is an integer of zero or greater.

In some embodiments, R¹ is an alkyl, alkenyl, heteroalkyl, cycloalkyl, heterocycloalkyl, aryl or heteroaryl group.

In some embodiments, R¹ has one of the following structures:

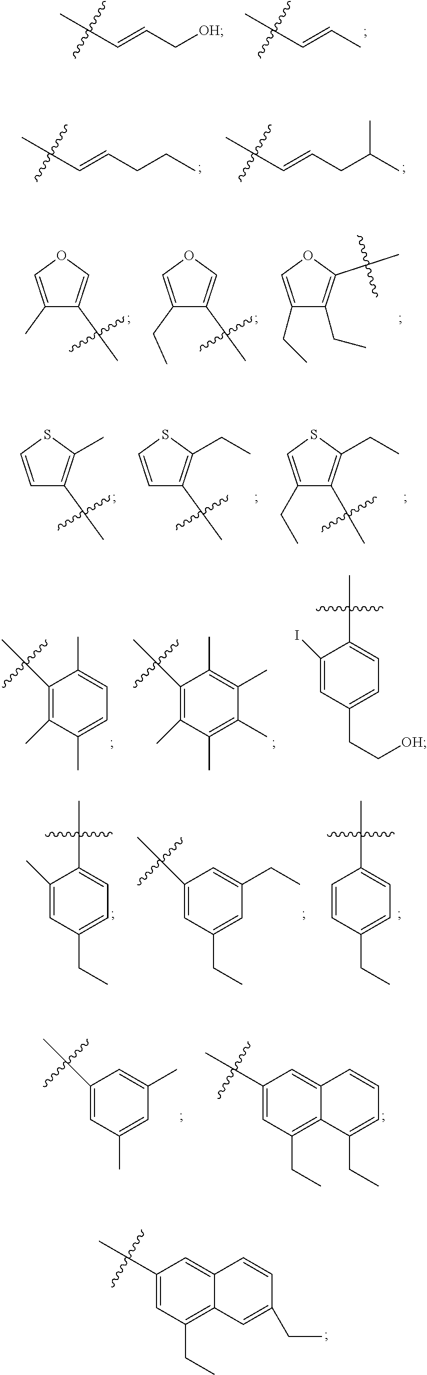

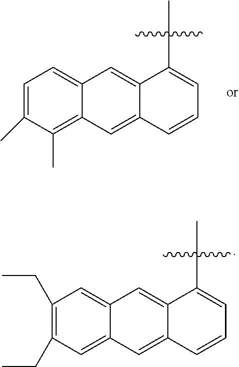 [SMILES: *c1cccc2cc3c(C)c(C)ccc3cc12 ; *c1cccc2cc3cc(CC)c(CC)cc3cc12]

In some embodiments, R² is an aliphatic polyol having 20 or fewer carbon atoms.

In some embodiments, R² is an alkyl, cycloalkyl or heteroalkyl diol or an alkyl, cycloalkyl or heteroalkyl triol.

In some embodiments, R² has one of the following structures:

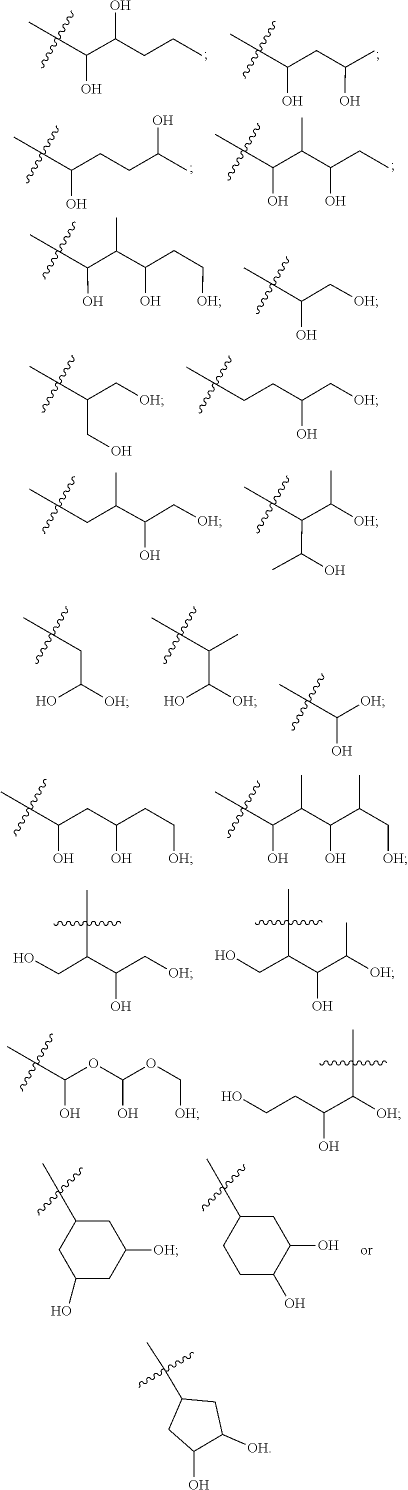

In some embodiments, R³ has one of the following structures:

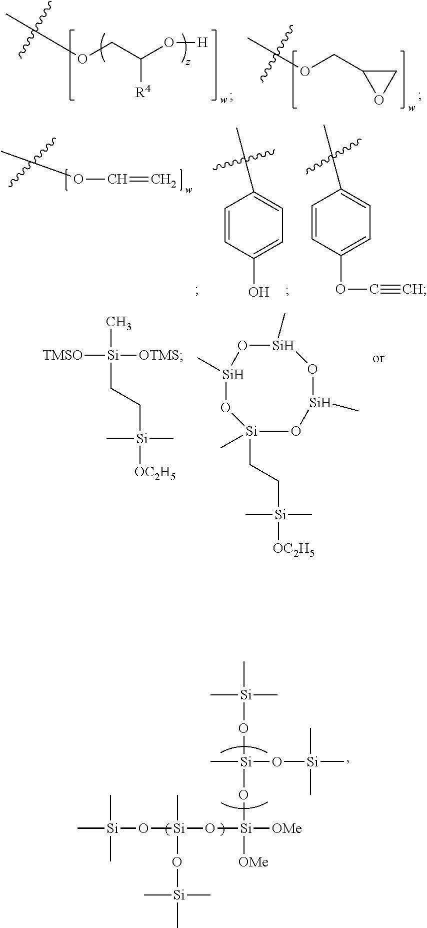

wherein:
R⁴ is, at each occurrence, H, alkyl, heteroalkyl, aryl, or heteroaryl;
z is an integer of 1 to 300; and
w is an integer of 1 to 6.

In some embodiments, R⁴ is a cyclic or noncyclic, saturated or unsaturated, substituted or unsubstituted, or branched or unbranched C₁-C₁₂ aliphatic or aromatic group. In some embodiments, R⁴ is a unsubstituted or halogen-substituted C₁-C₁₂ alkyl group. In some embodiments, R⁴ is C₂-C₁₂ alkyl interrupted by —S—, —P—, —P(O₂)—, —C(═O)S—, C(═O)O—, —O—, —N—, —C(═O)N—, —SO₂O—, —SO₂S—, —SO—, —SO₂—, —C₆H₆—O—, —C₆H₆—O—C(═O)O—, or —C(═O)—.

In some embodiments, L¹, L², and L³ are independently a cyclic or noncyclic, saturated or unsaturated, substituted or unsubstituted, or branched or unbranched C₁-C₁₂ aliphatic or aromatic group. In some embodiments, L¹, L², and L³ are independently a unsubstituted or halogen-substituted C₁-C₁₂ alkylene group. In some embodiments, L¹, L², and L³ are independently C₂-C₁₂ alkylene interrupted by —S—, —P—, —P(O₂)—, —C(═O)S—, —C(═O)O—, —O—, —N—, —C(═O)N—, —SO₂O—, —SO₂S—, —SO—, —SO₂—, —C₆H₆—O—, —C₆H₆—O—C(═O)O—, or —C(═O)—.

In some embodiments, p is 0, and the polymer 302 thus does not contain the crosslinking group 316. Accordingly, the polymer 302 has the following structure (IA):

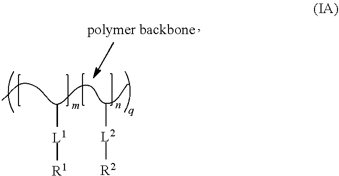

wherein L¹ and L² are independently a cyclic or noncyclic, saturated or unsaturated, substituted or unsubstituted, or branched or unbranched C₁-C₁₂ aliphatic or aromatic group. In some embodiments, L¹ and L² are independently a unsubstituted or halogen-substituted C₁-C₁₂ alkylene group. In some embodiments, L¹ and L² are independently C₂-C₁₂ alkylene interrupted by –S—, —P—, —P(O₂)—, —C(═O)S—, —C(═O)O—, —O—, —N—, —C(═O)N—, —SO₂O—, —SO₂S—, —SO—, —SO₂—, —C₆H₆—O—, —C₆H₆—O—C(═O)O—, or —C(═O)—.

In some embodiments, the polymer 302 of structure (IA) has the following structure (IB):

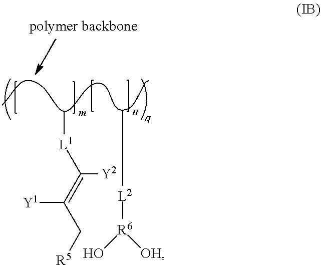

wherein:
Y¹ and Y² are, at each occurrence, independently OR^{a}, NR^{b}R^{c}, F, Cl, Br, or I;
R⁵ is, at each occurrence, H, OH, unsubstituted or halogen-substituted C₁-C₁₂ alkyl or C₂-C₁₂ heteroalkyl comprising at least one of —S—, —P—, —P(O₂)—, —C(═O)S—, —C(═O)O—, —O—, —N—, —C(═O)N—, —SO₂O—, —SO₂S—, —SO—, —SO₂—, —C₆H₆—O—, —C₆H₆—O—C(═O)O— or —C(═O)—, or C₅-C₁₈ aryl;
R⁶ is, at each occurrence, C₁-C₁₂ alkylene or C₃-C₁₈ cycloalkylene; and
R^{a}, R^{b} and R^{c} are, at each occurrence, independently H or C₁-C₁₂ alkyl.

In some embodiments of structure (I), m is, at each occurrence, independently an integer from 1 to 100, for example, from 1 to 50, from 1 to 25 or from 1 to 10. In certain embodiments, m is 1, 2, 3, 4, 5, 6, 7, 8, 9, 10, 11, 12, 13, 14, 15, 16, 17, 18, 19, 20, 21, 22, 23, 24, or 25.

In some embodiments of structure (I), n is, at each occurrence, independently an integer from 1 to 100, for example, from 1 to 50, from 1 to 25 or from 1 to 10. In certain embodiments, n is 1, 2, 3, 4, 5, 6, 7, 8, 9, 10, 11, 12, 13, 14, 15, 16, 17, 18, 19, 20, 21, 22, 23, 24, or 25.

In some embodiments of structure (I), p is, at each occurrence, independently an integer from 0 to 100, for example, from 0 to 50, from 0 to 25 or from 0 to 10. In certain embodiments, p is 1, 2, 3, 4, 5, 6, 7, 8, 9, 10, 11, 12, 13, 14, 15, 16, 17, 18, 19, 20, 21, 22, 23, 24, or 25.

In some embodiments of structure (I), q is, at each occurrence, independently an integer from 1 to 100, for example, from 1 to 50, from 1 to 25 or from 1 to 10. In certain embodiments, q is 1, 2, 3, 4, 5, 6, 7, 8, 9, 10, 11, 12, 13, 14, 15, 16, 17, 18, 19, 20, 21, 22, 23, 24, or 25.

FIG. 4 illustrates a second exemplary polymer 300 (referred to as polymer 304) that can be used in the middle material layer 220, in accordance with some embodiments. Unlike the polymer 302 in which both of hydrogen donor group 312 and water donor group 314 are attached to the polymer backbone 310 via respective linkers L¹ and L², in polymer 304, the water donor group 314 is bonded to the hydrogen donor group 312, and thus is bonded to the polymer backbone 310 via the hydrogen donor group 312. In some embodiments, the polymer 304 may include a first repeating unit A having a pendant hydrogen donor group and a water donor group bonded to the hydrogen donor group; and a second repeating unit C having a pendant crosslinking group.

In some embodiments, the polymer 304 has the following structure (II):

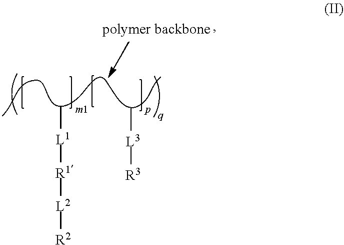

wherein:
L¹, L² and L³ are, at each occurrence, independently an optional alkylene, alkenylene, alkynylene, heteroalkylene, heteroalkenylene, heteroalkynylene, cycloalkylene, heterocycloalkylene, arylene, or heteroarylene linker;
R^{1′} is, at each occurrence, a hydrogen donor group;
R² is, at each occurrence, a water donor group;
R³ is, at each occurrence, a crosslinking group;
m1 and q are independently an integer of one or greater; and
p is an integer of zero or greater.

In some embodiments, R^{1′} is an alkylene, alkenylene, heteroalkylene, cycloalkylene, heterocycloalkylene, arylene, or heteroarylene group comprising a cleavable C—H bond.

In some embodiments, R^{1′} has the following structure:

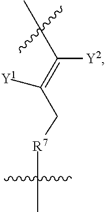

wherein:
Y¹ and Y² are, at each occurrence, independently OR^{a}, NR^{b}R^{c}, F, Cl, Br, or I;
R⁷ is, at each occurrence, C₁-C₁₂ alkylene or C₃-C₁₈ cycloalkylene; and
R^{a}, R^{b} and R^{c} are, at each occurrence, independently H or C₁-C₁₂ alkyl.

In some embodiments, R² is an aliphatic polyol having 20 or fewer carbon atoms.

In some embodiments, R² is an alkyl, cycloalkyl or heteroalkyl diol or an alkyl, cycloalkyl or heteroalkyl triol.

In some embodiments, R² has one of the following structures:

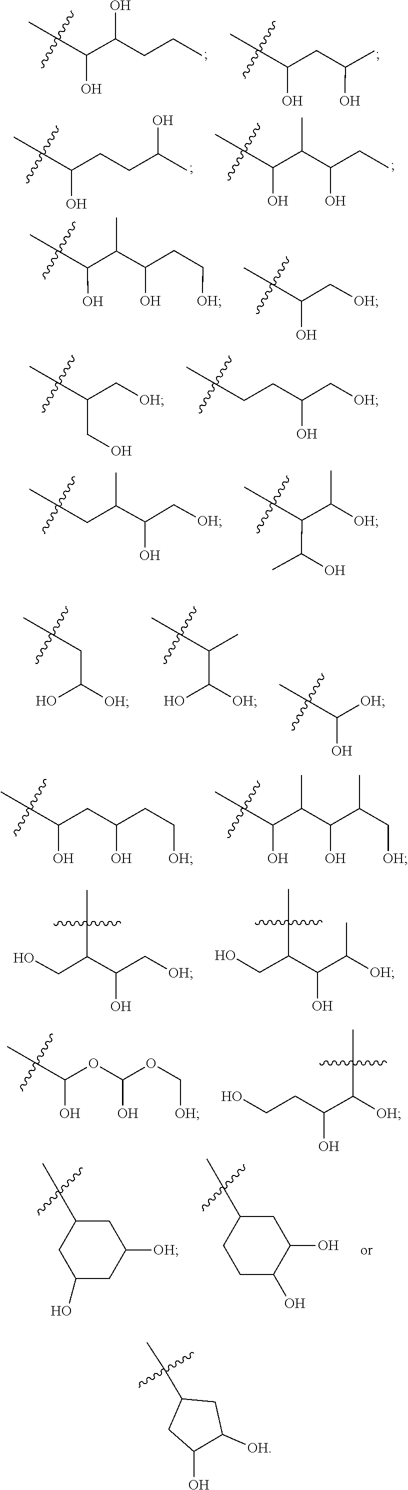

In some embodiments, R³ has one of the following structures:

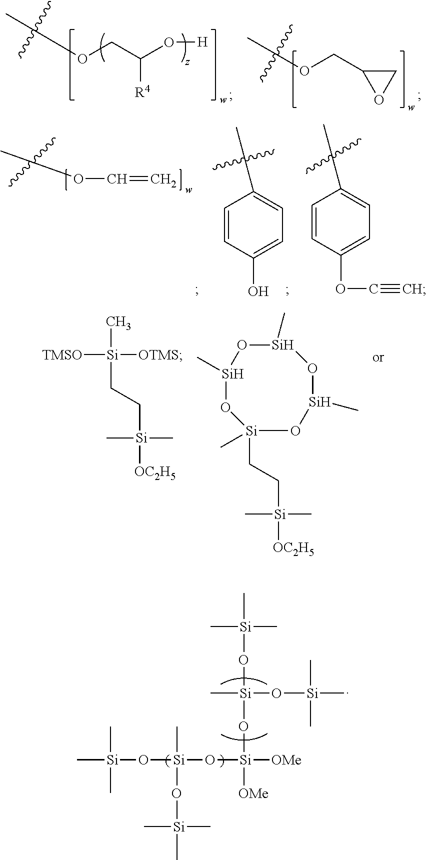

wherein:
R⁴ is, at each occurrence, H, alkyl, heteroalkyl, aryl, or heteroaryl;
z is an integer of 1 to 300; and
w is an integer of 1 to 6.

In some embodiments, R⁴ is a cyclic or noncyclic, saturated or unsaturated, substituted or unsubstituted, or branched or unbranched C₁-C₁₂ aliphatic or aromatic group. In some embodiments, R⁴ is a unsubstituted or halogen-substituted C₁-C₁₂ alkyl group. In some embodiments, R⁴ is C₂-C₁₂ alkyl interrupted by —S—, —P—, —P(O₂)—, —C(═O)S—, —C(═O)O—, —O—, —N—, —C(═O)N—, —SO₂O—, —SO₂S—, —SO—, —SO₂—, —C₆H₆—O—, —C₆H₆—O—C(═O)O—, or —C(═O)—.

In some embodiments, L¹, L², and L³ are independently a cyclic or noncyclic, saturated or unsaturated, substituted or unsubstituted, or branched or unbranched C₁-C₁₂ aliphatic or aromatic group. In some embodiments, L¹, L², and L³ are independently a unsubstituted or halogen-substituted C₁-C₁₂ alkylene group. In some embodiments, L¹, L², and L³ are independently C₂-C₁₂ alkylene interrupted by —S—, —P—, —P(O₂)—, C(═O)S—, —C(═O)O—, —O—, —N—, —C(═O)N—, —SO₂O—, —SO₂S—, —SO—, —SO₂—, —C₆H₆—O—, —C₆H₆—O—C(═O)O—, or —C(═O)—.

In some embodiments, p is 0, and the polymer 304 does not contain a crosslinking unit. Accordingly, the polymer 304 has the following structure (IIA):

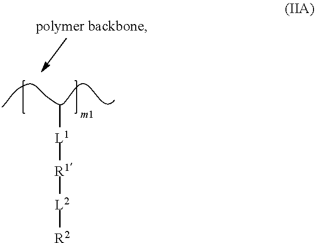

In some embodiments of structure (II), m1 is, at each occurrence, independently an integer from 1 to 100, for example, from 1 to 50, from 1 to 25 or from 1 to 10. In certain embodiments, m1 is 1, 2, 3, 4, 5, 6, 7, 8, 9, 10, 11, 12, 13, 14, 15, 16, 17, 18, 19, 20, 21, 22, 23, 24, or 25.

In some embodiments of structure (II), p is, at each occurrence, independently an integer from 0 to 100, for example, from 0 to 50, from 0 to 25 or from 0 to 10. In certain embodiments, p is 1, 2, 3, 4, 5, 6, 7, 8, 9, 10, 11, 12, 13, 14, 15, 16, 17, 18, 19, 20, 21, 22, 23, 24, or 25.

In some embodiments of structure (II), q is, at each occurrence, independently an integer from 1 to 100, for example, from 1 to 50, from 1 to 25 or from 1 to 10. In certain embodiments, q is 1, 2, 3, 4, 5, 6, 7, 8, 9, 10, 11, 12, 13, 14, 15, 16, 17, 18, 19, 20, 21, 22, 23, 24, or 25.

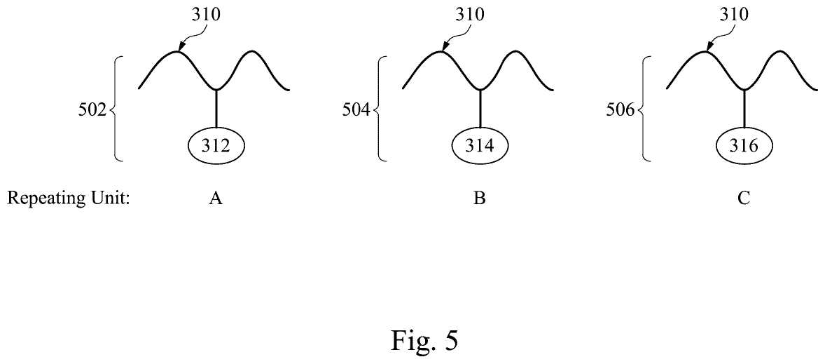

Referring to FIG. 5, in some embodiments, the middle material layer 220 includes a coating composition comprising a mixture of polymers 502, 504, 506. The polymer 502 is made of repeating unit A having a pendant hydrogen donor group 312, the polymer 504 is made of repeating unit B having a pendant water donor group 314, and the polymer 506 is made of repeating unit C having a pendant crosslinking groups 316.

In some embodiments, the hydrogen donor group 312 is about 1 wt. % to about 70 wt. % of the polymer 502. In some embodiments, the water donor group 314 is about 1 wt. % to about 70 wt. % of the polymer 504. In some embodiments, the crosslinking group 316 is about 10 wt. % to about 70 wt. % of the polymer 506. In some embodiments, the hydrogen donor group 312, the water donor group 314, and the crosslinking group 316 are each bonded to the polymer backbones 310 by respective linkers selected from cyclic or noncyclic, saturated or unsaturated, substituted or unsubstituted, or branched or unbranched C₁-C₁₂ aliphatic or aromatic groups, for example, unsubstituted or halogen-substituted C₁-C₁₂ alkylene groups or C₂-C₁₂ alkylene groups interrupted by —S—, —P—, —P(O₂)—, —C(═O)S—, —C(═O)O—, —O—, —N—, —C(═O)N—, —SO₂O—, —SO₂S—, —SO—, —SO₂—, —C₆H₆—O—, —C₆H₆—O—C(═O)O—, or —C(═O)—.

In some embodiments, the first polymer 502 has the following structure (III):

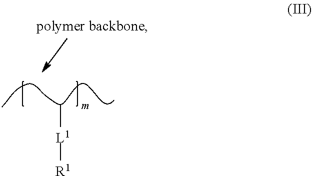

wherein:
L¹ is, at each occurrence, independently an optional alkylene, alkenylene, alkynylene, heteroalkylene, heteroalkenylene, heteroalkynylene, cycloalkylene, heterocycloalkylene, arylene, or heteroarylene linker;
R¹ is, at each occurrence, a hydrogen donor group; and
m is an integer of one or greater.

In some embodiments, L¹ is a cyclic or noncyclic, saturated or unsaturated, substituted or unsubstituted, or branched or unbranched C₁-C₁₂ aliphatic or aromatic group. In some embodiments, L¹ is a unsubstituted or halogen-substituted C₁-C₁₂ alkylene group. In some embodiments, L¹ is C₂-C₁₂ alkylene interrupted by —S—, —P—, —P(O₂)—, —C(═O)S—, —C(═O)O—, —O—, —N—, —C(═O)N—, —SO₂O—, —SO₂S—, —SO—, —SO₂—, —C₆H₆—O—, —C₆H₆—O—C(═O)O—, or —C(═O)—.

In some embodiments, R¹ is an alkyl, alkenyl, heteroalkyl, cycloalkyl, heterocycloalkyl, aryl, or heteroaryl group.

In some embodiments, R¹ has one of the following structures:

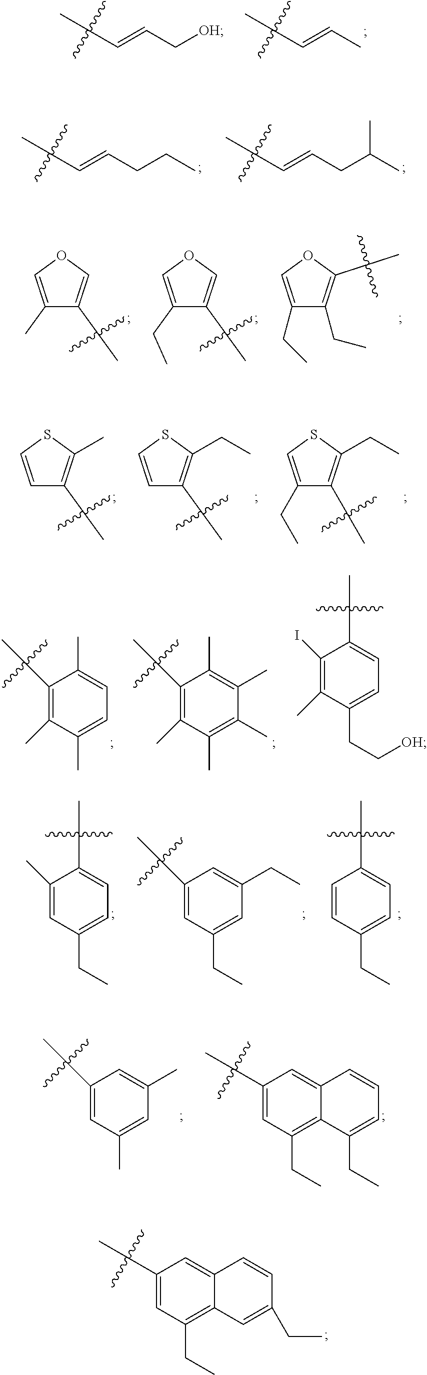

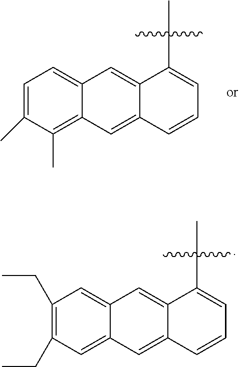 [SMILES: *c1cccc2cc3c(C)c(C)ccc3cc12 ; *c1cccc2cc3cc(CC)c(CC)cc3cc12]

In some embodiments, m is an integer from 1 to 100, for example, from 1 to 50, from 1 to 25 or from 1 to 10. In certain embodiments, m is 1, 2, 3, 4, 5, 6, 7, 8, 9, 10, 11, 12, 13, 14, 15, 16, 17, 18, 19, 20, 21, 22, 23, 24, or 25.

In some embodiments, the second polymer 504 has the following structure (IV):

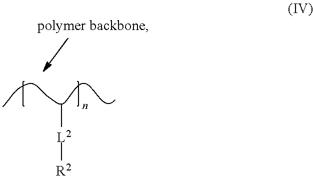

wherein:
L² is, at each occurrence, independently an optional alkylene, alkenylene, alkynylene, heteroalkylene, heteroalkenylene, heteroalkynylene, cycloalkylene, heterocycloalkylene, arylene, or heteroarylene linker;
R² is, at each occurrence, a water donor group; and
n is an integer of one or greater.

In some embodiments, L² a cyclic or noncyclic, saturated or unsaturated, substituted or unsubstituted, or branched or unbranched C₁-C₁₂ aliphatic or aromatic group. In some embodiments, L² is a unsubstituted or halogen-substituted C₁-C₁₂ alkylene group. In some embodiments, L² is C₂-C₁₂ alkylene interrupted by —S—, —P—, —P(O₂)—, —C(═O)S—, —C(═O)O—, —O—, —N—, —C(═O)N—, —SO₂O—, —SO₂S—, —SO—, —SO₂—, —C₆H₆—O—, —C₆H₆—O—C(═O)O—, or —C(═O)—.

In some embodiments, R² is an aliphatic polyol having 20 or fewer carbon atoms.

In some embodiments, R² is an alkyl, cycloalkyl or heteroalkyl diol or an alkyl, cycloalkyl or heteroalkyl triol.

In some embodiments, R² has one of the following structures:

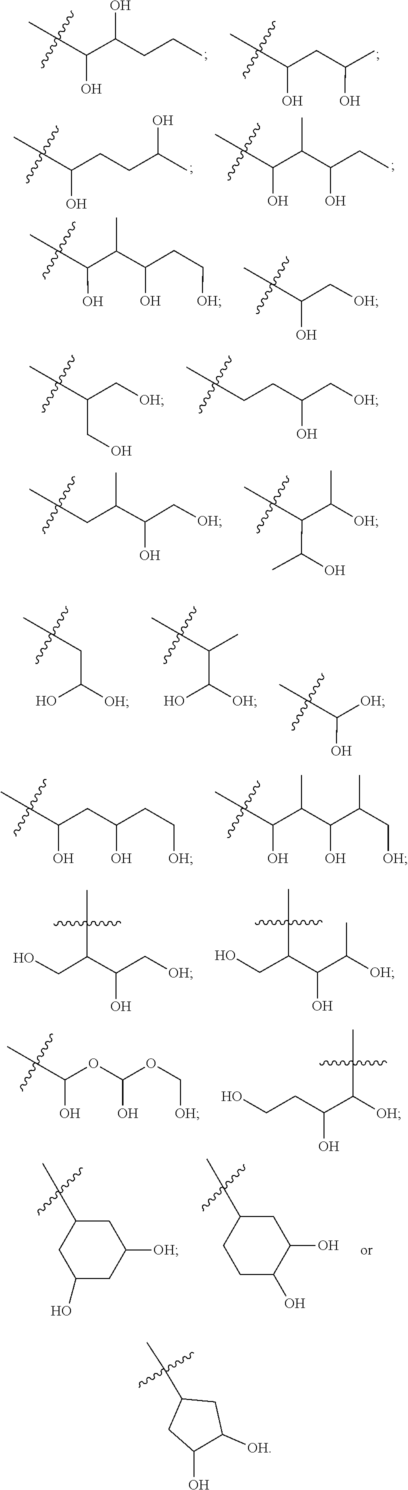

In some embodiments, n is an integer from 1 to 100, for example, from 1 to 50, from 1 to 25 or from 1 to 10. In certain embodiments, n is 1, 2, 3, 4, 5, 6, 7, 8, 9, 10, 11, 12, 13, 14, 15, 16, 17, 18, 19, 20, 21, 22, 23, 24, or 25.

In some embodiments, the polymer 506 has the following structure (V):

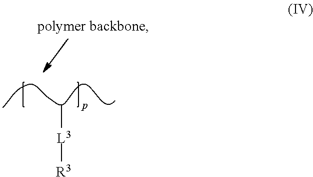

wherein:
L³ is, at each occurrence, independently an optional alkylene, alkenylene, alkynylene, heteroalkylene, heteroalkenylene, heteroalkynylene, cycloalkylene, heterocycloalkylene, arylene, or heteroarylene linker;
R³ is, at each occurrence, a crosslinking group; and
p is an integer of one or greater.

In some embodiments, L³ a cyclic or noncyclic, saturated or unsaturated, substituted or unsubstituted, or branched or unbranched C₁-C₁₂ aliphatic or aromatic group. In some embodiments, L³ is a unsubstituted or halogen-substituted C₁-C₁₂ alkylene group. In some embodiments, L³ is C₂-C₁₂ alkylene interrupted by —S—, —P—, —P(O₂)—, —C(═O)S—, —C(═O)O—, —O—, —N—, —C(═O)N—, —SO₂O—, —SO₂S—, —SO—, —SO₂—, —C₆H₆—O—, —C₆H₆—O—C(═O)O—, or —C(═O)—.

In some embodiments, R³ has one of the following structures:

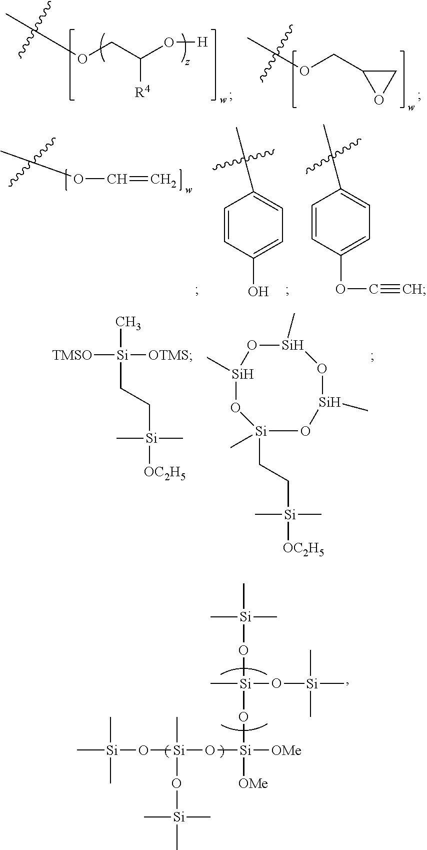

wherein:
R⁴ is, at each occurrence, H, alkyl, heteroalkyl, aryl, or heteroaryl;
z is an integer of 1 to 300; and
w is an integer of 1 to 6.

In some embodiments, R⁴ is a cyclic or noncyclic, saturated or unsaturated, substituted or unsubstituted, or branched or unbranched C₁-C₁₂ aliphatic or aromatic group. In some embodiments, R⁴ is a unsubstituted or halogen-substituted C₁-C₁₂ alkyl group. In some embodiments, R⁴ is C₂-C₁₂ alkyl interrupted by —S—, —P—, —P(O₂)—, —C(═O)S—, —C(═O)O—, —O—, —N—, —C(═O)N—, —SO₂O—, —SO₂S—, —SO—, —SO₂—, —C₆H₆—O—, —C₆H₆—O—C(═O)O—, or —C(═O)—.

In some embodiments, p is an integer from 1 to 100, for example, from 1 to 50, from 1 to 25 or from 1 to 10. In certain embodiments, p is 1, 2, 3, 4, 5, 6, 7, 8, 9, 10, 11, 12, 13, 14, 15, 16, 17, 18, 19, 20, 21, 22, 23, 24, or 25.

In some embodiments, the BARC composition includes an acid generator. In some embodiments, the acid generator includes a thermal acid generator (TAG), a photoacid generator (PAG), or a combination thereof.

In some embodiments, the acid generator includes a thermal generator that generates an acid upon heating. The thermally generated acid triggers the crosslinking reaction for certain crosslinking groups 316. In some embodiments, the thermal acid generator is selected from the group consisting of:

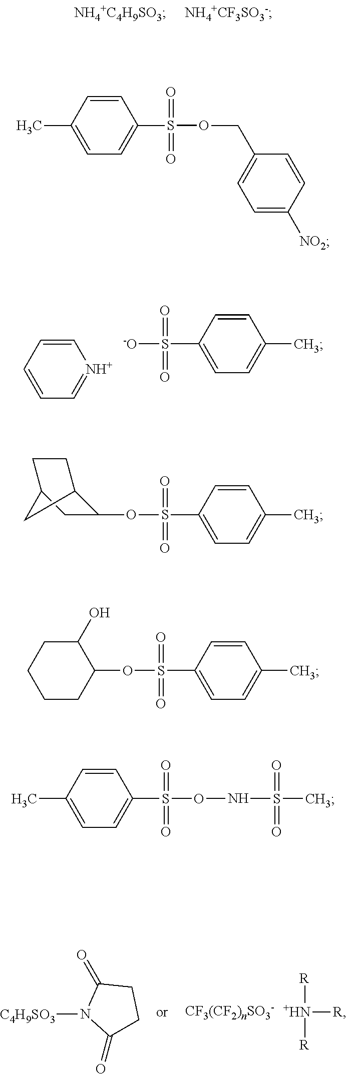

wherein:
R is H, alkyl, heteroalkyl, cycloalkyl, heterocycloalkyl, aryl or heteroaryl; and
n is an integer of 1 to 4.

In some embodiments, R is a cyclic or noncyclic, saturated or unsaturated, substituted or unsubstituted, or branched or unbranched C₁-C₁₂ aliphatic or aromatic group. In some embodiments, R is a unsubstituted or halogen-substituted C₁-C₁₂ alkyl group. In some embodiments, R is C₂-C₁₂ alkyl interrupted by —S—, —P—, —P(O₂)—, —C(═O)S—, —C(═O)O—, —O—, —N—, —C(═O)N—, —SO₂O—,—SO₂S—, —SO—, —SO₂—, —C₆H₆—O—, —C₆H₆—O—C(═O)O—, or —C(═O)—.

In some embodiments, the concentration of the thermal acid generator ranges from about 0.5 wt. % to about 30 wt. % based on the total weight of the material layer composition. At concentrations of the thermal acid generator below the disclosed ranges, there may not be enough acid generated to promote the crosslinking reaction of the crosslinking group 316. At concentrations of the thermal acid generator greater than the disclosed ranges, there may not be a significant improvement in the efficiency of the crosslinking reaction of the crosslinking group 316.

In some embodiments, the acid generator includes a photoacid generator (PAG) that generates an acid when exposing to radiation, for example, EUV radiation or E-beam radiation. The generated acid triggers the condensation rection of the water donor group 314 to provide water into the photoresist layer.

In some embodiments, the photoacid generator may include a combination of a cation and an anion. Examples of photoacid generators according to embodiments of the disclosure include α-(trifluoromethylsulfonyloxy)-bicyclo[2.2.1]hept-5-ene-2,3-dicarb-o-ximide (MDT), N-hydroxy-naphthalimide (DDSN), benzoin tosylate, t-butylphenyl-α-(p-luenesulfonyloxy) toacetate and t-butyl-α-(p-toluenesulfonyloxy) acetate, triarylsulfonium and diaryliodonium hexafluoroantimonates, hexafluoroarsenates, trifluoromethanesulfonates, iodonium perfluorooctanesulfonate, N-camphorsulfonyloxynaphthalimide, N-pentafluorophenylsulfonyloxynaphthalimide, ionic iodonium sulfonates such as diaryl iodonium (alkyl or aryl) sulfonate and bis-(di-t-butylphenyl) iodonium camphanylsulfonate, perfluoroalkanesulfonates such as perfluoropentanesulfonate, perfluorooctanesulfonate, perfluoromethanesulfonate, aryl (e.g., phenyl or benzyl) triflates such as triphenylsulfonium triflate or bis(t-butylphenyl) iodonium triflate; pyrogallol derivatives (e.g., trimesylate of pyrogallol), trifluoromethanesulfonate esters of hydroxyimides, α,60 ′-bis-sulfonyl-iazomethanes, dsulfonate esters of nitro-substituted benzyl alcohols, naphthoquinone-4-diazides, alkyl disulfones, or the like.

In some embodiments, the cation is selected from the group consisting of:

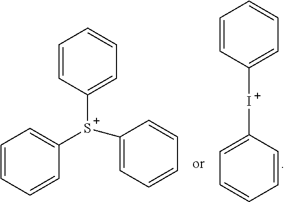 [SMILES: c1ccc([S+](c2ccccc2)c2ccccc2)cc1 ; c1ccc([I+]c2ccccc2)cc1]

In some embodiments, the anion is selected from the group consisting of:

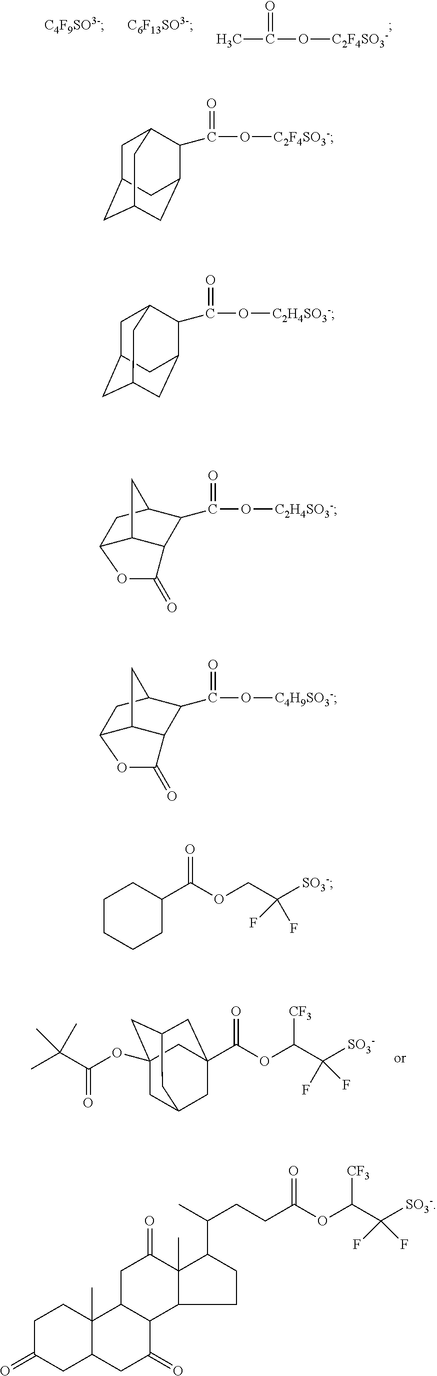

In some embodiments, the concentration of the photo acid generator ranges from about 0.5 wt. % to about 30 wt. % based on the total weight of the polymer(s) (e.g., polymer 300, 502, 504 and 506). At concentrations of the photoacid generator below the disclosed ranges, there may not be enough acid generated to promote the condensation reaction of the water donor group 314. At concentrations of the photoacid generator greater than the disclosed ranges, there may not be a significant improvement in the efficiency of the condensation reaction of the water donor group 314.

The BARC composition includes a solvent in some embodiments. The solvent can be any suitable solvent. In some embodiments, the solvent is one or more selected from propylene glycol methyl ether acetate (PGMEA), propylene glycol monomethyl ether (PGME), 1-ethoxy-2-propanol (PGEE), γ-butyrolactone (GBL), cyclohexanone (CHN), ethyl lactate (EL), methanol, ethanol, propanol, n-butanol, acetone, dimethylformamide (DMF), isopropanol (IPA), tetrahydrofuran (THF), methyl isobutyl carbinol (AMC), n-butyl acetate (nBA), and 2-heptanone (MAK).

In some embodiments, the polymer 300 or the mixture of polymers 502, 504, 506 and the acid generator are added to the solvent for application, and the middle material layer 220 is formed by applying the BARC composition onto the top surface of the bottom material layer 210 if present, or onto the substrate 202, for example, by spin coating or imprint. Alternatively, the middle material layer 220 may be formed by a suitable deposition process, such as, for example, CVD, PVD or ALD. In some embodiments, the middle material layer 220 may be formed to have a thickness ranging from about 5 Å to about 500 Å. Layer thicknesses less than the disclosed ranges may be insufficient to provide adequate photoresist adhesion and anti-reflective properties. Layer thicknesses greater than the disclosed ranges may be unnecessarily thick and may not provide further improvement in photoresist adhesion and anti-reflective properties.

Referring to FIGS. 1 and 2C, the method 100 proceeds to operation 106, in which a first baking process is performed, thereby forming a crosslinked middle material layer 222, in accordance with some embodiments. FIG. 2C is a cross-sectional view of the semiconductor device 200 after performing the first baking process, in accordance with some embodiments.

The first baking process is performed at a temperature for a period of time that is sufficient to cause the crosslinking groups 316 to react with each other and to bond the individual polymer (e.g., polymer 300, 502, 504 and 506) in the middle material layer 220 into polymer networks; but does not cause the decomposition of the hydrogen donor group 312 and the water donor group 314. In some embodiments, the first baking process is performed at a temperature ranging from about 100° C. to about 400° C. In certain embodiments, the first baking process is performed at a temperature of about 80° C. to about 200° C. for about 20 seconds to about 3 minutes. In other embodiments, the first baking process is performed at a temperature of about 100° C. to about 250° C. for about 10 seconds to about 2 minutes. The first baking process forms a crosslinked middle material layer 222 with a good solvent resistance to allow application of the photoresist layer without dissolving the crosslinked middle material layer 222.

Referring to FIGS. 1 and 2D, the method 100 proceeds to operation 108, in which a photoresist layer 230 is deposited over the crosslinked middle material layer 222, in accordance with some embodiments. FIG. 2D is a cross-sectional view of the semiconductor device 200 of FIG. 2C after depositing the photoresist layer 230 over the crosslinked middle material layer 222. The photoresist layer 230 may be a top material layer of the trilayer patterning stack.

The photoresist layer 230 is a photosensitive layer that is patternable by exposure to radiation. Typically, the chemical properties of the photoresist regions struck by incident radiation change in a manner that depends on the type of photoresist used. The photoresist layer 230 includes either a positive tone resist or a negative tone resist. A positive tone resist refers to a photoresist material that when exposed to radiation, such as UV light, becomes soluble in a developer, while the region of the photoresist that is non-exposed (or exposed less) is insoluble in the developer. A negative tone resist, on the other hand, refers to a photoresist material that when exposed to radiation becomes insoluble in the developer, while the region of the photoresist that is non-exposed (or exposed less) is soluble in the developer. The region of a negative resist that becomes insoluble upon exposure to radiation may become insoluble due to a cross-linking reaction caused by the exposure to radiation.

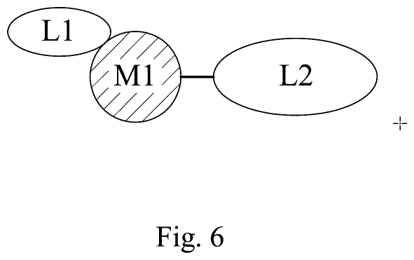

In some embodiments, the photoresist layer 230 includes a high sensitivity photoresist composition. In some embodiments, the high sensitivity photoresist composition includes a metal that has a high absorbance for EUV radiation. In some embodiments, the photoresist layer 230 may include an organometallic compound that includes a metal core M1 coordinated with a first photo-cleavable ligand L1 and a second non-photo-cleavable ligand L2, as shown in FIG. 6. Although only one first ligand L1 and one second ligand L2 are shown, any numbers of first ligand L1 and second ligand can be contemplated.

In some embodiments, the metal core M1 includes one or more metal atoms. In some embodiments, the one or more metal atoms are selected from the group consisting of Hf, Zr, Ti, Cr, W, Mo, Fe, Ru, Os, Co, Rh, Ir, Ni, Pd, Pt, Cu, Ag, Au, Zn, Cd, Al, Ga, Ti, Ge, Sn, Pb, Sb, and Bi.

In some embodiments, the first photo-cleavable ligand L1 is an aliphatic or aromatic, cyclic or non-cyclic C1-C30 group, wherein the C1-C30 group is unsubstituted or substituted with one or more selected from the group consisting of —I, —Br, —Cl, —F, —NH₂, —COOH, —OH, —SH, —N₃, —S(═O)—, an alkene group, an alkyne group, an imine group, an ether group, an ester group, an aldehyde group, a ketone group, an amide group, a sulfone group, an acetic acid group, a cyanide group, an allene group, an alcohol group, a diol group, an amine group, a phosphine group, a phosphite group, an aniline group, a pyridine group, and a pyrrole group.

The second ligand L2 is different from the first ligand L1. In some embodiments, the second ligand L2 includes C₃-C₁₂ aliphatic or aromatic groups. The aliphatic or aromatic groups may be unbranched or branched with cyclic, or noncyclic saturated pendant groups containing 1-9 carbons, including alkyl groups, alkenyl groups, and phenyl groups. The branched groups may be further substituted with oxygen or halogen. In some embodiments, the C₃-C₁₂ aliphatic or aromatic groups include heterocyclic groups. In some embodiments, the C₃-C₁₂ aliphatic or aromatic groups are attached to the metal by an ether or ester linkage. In other embodiments, the second ligand L2 includes branched or unbranched, cyclic or non-cyclic, saturated organic groups, including C₁-C₇ alkyl groups or C₁-C₇ fluoroalkyl groups. In some embodiments, the C₁-C₇ alkyl groups or C₁-C₇ fluoroalkyl groups include one or more substituents selected from the group consisting of —CF₃,—SH, —OH, ═O, —S—, —P—, —PO₂, —C(═O)SH, —COOH, —C(═O)O—, —O—, —N—, —C(═O)NH, —SO₂OH, —SO₂SH, —SOH, and —SO₂—. In some embodiments, the second ligand L2 includes one or more substituents selected from the group consisting of —CF₃, —OH, —SH, and —COOH substituents.

In some embodiments, the organometallic compound has one of the following structures:

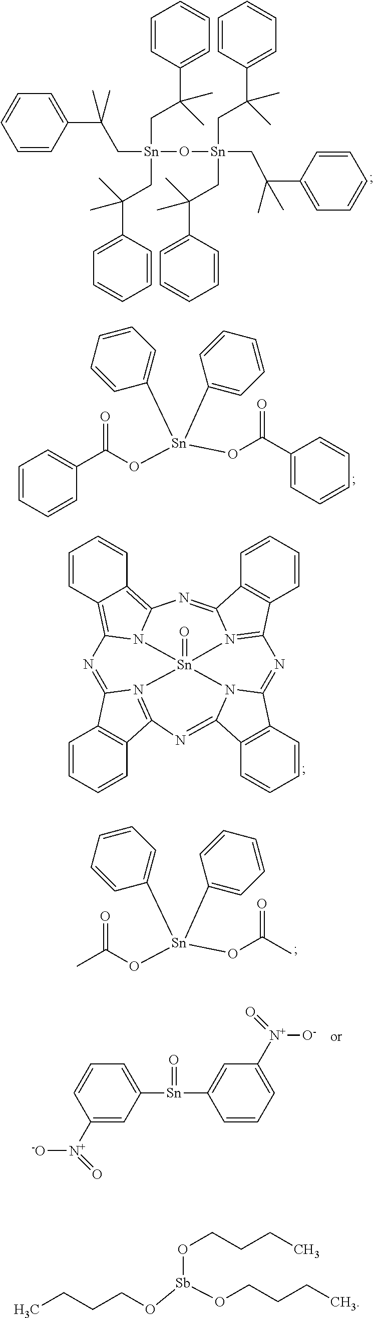

In some embodiments, the photoresist layer 230 is formed by applying a photoresist composition over the crosslinked coating layer 212 using, for example, spin coating. In some embodiments, the photoresist composition includes at least one kind of organometallic compounds and at least one kind of solvents. The amount of the organometallic compound in the photoresist composition may be from about 0.5% to 10% by weight. In some embodiments, the photoresist composition may include about 1% organometallic compound by weight. In some other embodiments, the photoresist layer 230 is formed by depositing the organometallic compound using CVD, PVD or ALD.

In some embodiments, after the photoresist layer 230 is disposed over the crosslinked middle material layer 222, a pre-exposure baking process may be performed to remove the solvent from the photoresist layer 230. In some embodiments, the pre-exposure baking process may be performed at a temperature of about 40° C. to about 140° C. for 10 seconds to 5 minutes. In some embodiments, the photoresist layer 230 is heated at a temperature of about 60° C. to about 120° C. for 20 seconds to 3 minutes.

Referring to FIGS. 1 and 2E, the method 100 proceeds to operation 110, in which the photoresist layer 230 is exposed to a radiation 240, in accordance with some embodiments. FIG. 2E is a cross-sectional view of the semiconductor device 200 after exposing the photoresist layer 230 to the radiation 240, in accordance with some embodiments.

The photoresist layer 230 is exposed to the radiation 240 from a light source through a photomask 250. The photomask 250 has a predefined pattern designed for an IC, based on a specification of the IC to be manufactured. The patterns of the photomask 250 correspond to patterns of materials that make up the various components of the IC device to be fabricated. For example, a portion of the IC design layout includes various IC features, such as an active region, gate electrode, source and drain, metal lines or vias of an interlayer interconnection, and openings for bonding pads, to be formed in the substrate 202.

In some embodiments, the photomask 250 includes first regions 252 and second regions 254. In the first regions 252, the radiation 240 is blocked by the photomask 250 to reach the photoresist layer 230, while in the second regions 254, the radiation 240 is not blocked by the photomask 250 and can pass through the photomask 250 to reach the photoresist layer 230. The selective exposure of the photoresist layer 230 through the photomask 250 thus forms exposed regions 230E and unexposed regions 230U in the photoresist layer 230.

In some embodiments, the radiation 240 is an EUV radiation (e.g., 13.5 nm). Alternatively, in some embodiments, the radiation 240 is a DUV radiation (e.g., from a 248 nm KrF excimer laser or a 193 nm ArF excimer laser), X-ray radiation, an e-beam radiation, an ion beam radiation, or other suitable radiations. In some embodiments, operation 110 is performed in a liquid (immersion lithography) or in a vacuum for EUV lithography and e-beam lithography.

During the exposure to the radiation 240, the metal core M1 in the organometallic compound absorbs the photon energy and generates a radical through metal core-ligand bond cleavage, the metal core radical then reacts with water to form a metal hydroxy, and the subsequent condensation of the metal hydroxy groups form metal-oxy clusters in the exposed regions 230E. The exposed regions 230E of the photoresist layer 230 may constitute a latent pattern. As the metallic clusters are substantially insoluble in a developer used in a later development process, the exposed regions 230E of the photoresist layer 230 that are irradiated by the radiation 240 are substantially insoluble in the developer. The unexposed regions 230U that are not irradiated by the radiation 240 do not undergo condensation reaction and are soluble in the developer. The difference in solubility allows the latent pattern to be developed in the developing process.

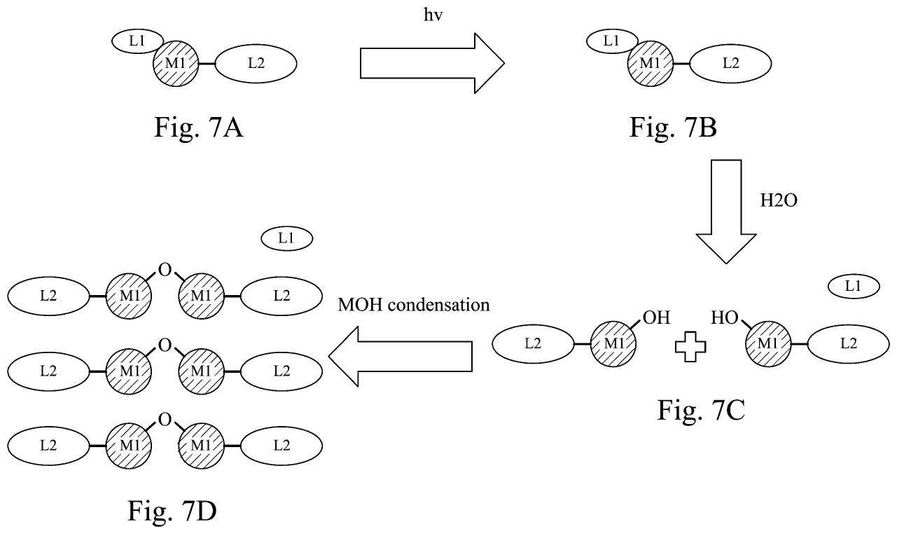

FIGS. 7A-7D illustrates a reaction of an organometallic compound undergoes when exposed to actinic radiation, in accordance with some embodiments. A organometallic compound, including a metal core M1 and a first photo-cleavable ligand L1 and a second non-photo-cleavable ligand L2, is exposed to actinic radiation, such as radiation 240, as shown in FIG. 7A. The first ligand L1 is converted to a radical upon the absorption of actinic radiation, as shown in FIG. 7B. The ligand radical L1 is subsequently cleaved from the metal core M1 (see FIG. 7C). The metal core M1 reacts with ambient water to form a metal hydroxide, as shown in FIG. 7C. The metal hydroxide groups react in a condensation reaction to form a metal oxide cluster, as shown in FIG. 7D.

Subsequently, the photoresist layer 230 may be subjected to a post-exposure baking process. The post-exposure baking process may be performed at a temperature from about 80° C. to about 350° C. for a duration from about 60 seconds to about 360 seconds. The diffusion of the photoacid can be accelerated by the post-exposure baking process, which in turn accelerates the condensation reaction of the water donor group 314 in the crosslinked middle material layer 222.

During the exposure process, the hydrogen donor group 312 in the crosslinked middle material layer 222 absorbs the energy to generate hydrogen radicals. The hydrogen radicals can diffuse into the photoresist layer 230 to stabilize the ligand radicals. The hydroxyl groups of the water donor group 314 in the crosslinked middle material layer 222 react with each other to produce water. The water can diffuses into the photoresist layer to facilitate formation of the metal hydroxide. As a result, by introducing hydrogen donor group in the middle material layer 220 to increase the ligand cleavage efficiency and by introducing water donor group in the middle material layer 220 to increase hydrolyzation efficiency, the dosage reduction can be achieved.

Referring to FIGS. 1 and 2F, the method 100 proceeds to operation 112, in which the photoresist layer 230 is developed using a developer to form a patterned photoresist layer 230P, in accordance with some embodiments. FIG. 2F is a cross-sectional view of the semiconductor device of FIG. 2E after forming the patterned photoresist layer 230P.

During the developing process, the developer is applied to the photoresist layer 230. The developer removes the exposed or unexposed portions 230E, 230U depending on the resist type. For example and as shown in FIG. 2F, the photoresist layer 230 comprises a negative-type resist, so the exposed portions 230E are not dissolved by the developer and remain over the crosslinked middle material layer 222 after the developing process. If the photoresist layer 230 comprises a positive-type resist, the exposed portions 230E would be dissolved by the developer, leaving the unexposed portions 230U over the crosslinked middle material layer 222 after the developing process.

The remaining exposed portions 230E (or unexposed portions 230U) define a pattern in the patterned photoresist layer 230P. The pattern contains one or more openings that expose portions of the underlying crosslinked middle material layer 222. Because of the small size of the organometallic oxide hydroxide clusters, the pattern in the patterned photoresist layer 230P is able to define features with pitches from about 24 nm to about 36 nm.

The developer may include alcohols, aromatic hydrocarbons, and the like. Examples of alcohols include, but are not limited to, methanol, ethanol, 1-butanol, and 4-Methyl-2-pentanol. Examples of aromatic hydrocarbons include, but are not limited to, xylene, toluene and benzene. In some embodiments, the developer is selected from at least one of methanol, 4-Methyl-2-pentanol and xylene.

The developer may be applied using any suitable methods. In some embodiments, the developer is applied by dipping the structure of FIG. 2E into a developer bath. In some embodiments, the developing solution is sprayed into the photoresist layer 230.

Referring to FIGS. 1 and 2G, the method 100 proceeds to operation 114, in which the crosslinked middle material layer 222 is etched using the patterned photoresist layer 230P as an etch mask, in accordance with some embodiments. FIG. 2G is a cross-sectional view of the semiconductor device 200 of FIG. 2F after etching the crosslinked middle material layer 222 using the patterned photoresist layer 230P as an etch mask.

Referring to FIG. 2G, the crosslinked middle material layer 222 is etched, using the patterned photoresist layer 230P as an etch mask, to form a patterned crosslinked middle material layer 222P. The etch can be a dry etch such as RIE or a wet etch. Etching of the crosslinked middle material layer 222 exposes portions of the underlying bottom material layer 210. If not completely consumed during the etching process, after etching the crosslinked middle material layer 222, the patterned photoresist layer 230P is removed by, for example, stripping or oxygen plasma.

Referring to FIGS. 1 and 2H, the method 100 proceeds to operation 116, in which the bottom material layer 210 is etched using the patterned crosslinked middle material layer 222P as an etch mask, in accordance with some embodiments. FIG. 2H is a cross-sectional view of the semiconductor device 200 of FIG. 2G after etching the bottom material layer 210 using the patterned crosslinked middle material layer 222P as an etch mask.

Referring to FIG. 2H, the bottom material layer 210 is etched, using the patterned crosslinked middle material layer 222P as an etch mask, to form a patterned bottom material layer 210P. Etching of the bottom material layer 210 exposes portions of the underlying substrate 202

An etching process may be performed to transfer the pattern in the patterned crosslinked middle material layer 222P to the bottom material layer 210. In some embodiments, the etching process is an anisotropic etch such as a dry etch. In some embodiments, the dry etch is a RIE or a plasma etch.

One or more fabrication processes, such as an etching process or an implantation process, may be performed to the substrate 202 using the patterned crosslinked middle material layer 222P and the patterned bottom material layer 210P as a mask.

One aspect of this description relates to method of forming a semiconductor device. The method includes depositing a coating layer over a substrate, forming a photoresist layer over the coating layer, exposing the photoresist layer to actinic radiation, and developing the photoresist layer to form a patterned photoresist layer. The coating layer includes a polymer containing a first unit having a pendant hydrogen donor group capable of producing a hydrogen radical upon exposure to the actinic radiation or heat, and a second repeating unit having a pendant water donor group capable of producing water upon exposure to the actinic radiation or heat.

Another aspect of this description relates to a method of forming a semiconductor device. The method includes depositing a coating layer that including a polymer over a substrate, forming a photoresist layer comprising an organometallic compound over the coating layer, exposing the photoresist layer to actinic radiation, and developing the photoresist layer to form a patterned photoresist layer. The polymer includes a first unit having a pendant hydrogen donor group and a water donor group bonded to the hydrogen donor group, and a second unit having a pendant crosslinking group.

Still another aspect of this description relates to a method of forming a semiconductor device. The method includes depositing a first material layer over a substrate, forming a second material layer over first material layer, baking the second material layer at an elevated temperature to form a crosslinked second material layer, depositing a photoresist layer over the crosslinked second material layer and forming a patterned photoresist layer. The second material layer includes a coating composition containing a mixture of a first polymer, a second polymer and a third polymer, and an acid generator. The first polymer includes a first repeating unit having a pendant hydrogen donor group, the second polymer includes a second repeating unit having a pendant water donor group, and the third polymer includes a third repeating unit having a pendant crosslinking group.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A photoresist stack for lithography patterning, comprising:
an anti-reflective coating (ARC) layer over a substrate, wherein the ARC layer is derived from a coating composition comprising a polymer having the following structure (I): 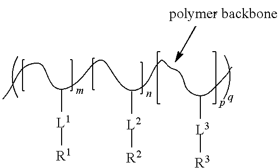
wherein:
L¹, L² and L³ are, at each occurrence, independently an optional alkylene, alkenylene, alkynylene, heteroalkylene, heteroalkenylene, heteroalkynylene, cycloalkylene, heterocycloalkylene, arylene or heteroarylene linker;
R¹ is, at each occurrence, a hydrogen donor group capable of generating a hydrogen radical upon exposure to actinic radiation or heat;
R² is, at each occurrence, a water donor group capable of producing water upon exposure to actinic radiation or heat;
R³ is, at each occurrence, a crosslinking group;
m, n and q are independently an integer of one or greater; and
p is an integer of zero or greater; and
a photoresist layer over the ARC layer, the photoresist layer comprising a organometallic compound.

2. The photoresist stack of claim 1, wherein R¹ comprises a linear, breached or cyclic aliphatic group or an aromatic group.

3. The photoresist stack of claim 2, wherein R¹ comprises a linear or branched C₃-C₂₀ alkenyl group or a C₁-C₄ alkyl-substituted aryl group.

4. The photoresist stack of claim 3, wherein R¹ has one of the following structures:

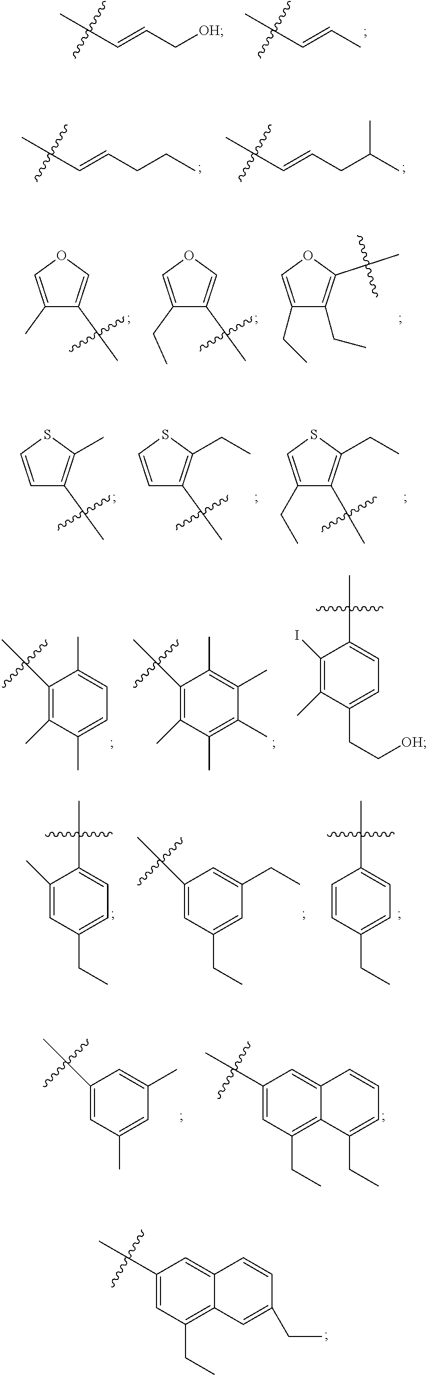

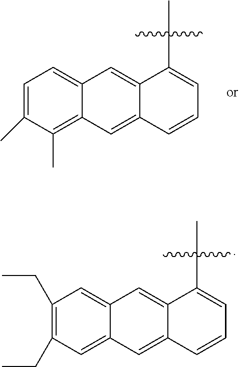 [SMILES: *c1cccc2cc3c(C)c(C)ccc3cc12 ; *c1cccc2cc3cc(CC)c(CC)cc3cc12]

5. The photoresist stack of claim 1, wherein R² comprises a linear, branched or cyclic aliphatic group having two or more hydroxy groups.

6. The photoresist stack of claim 5, wherein R² has one of the following structures:

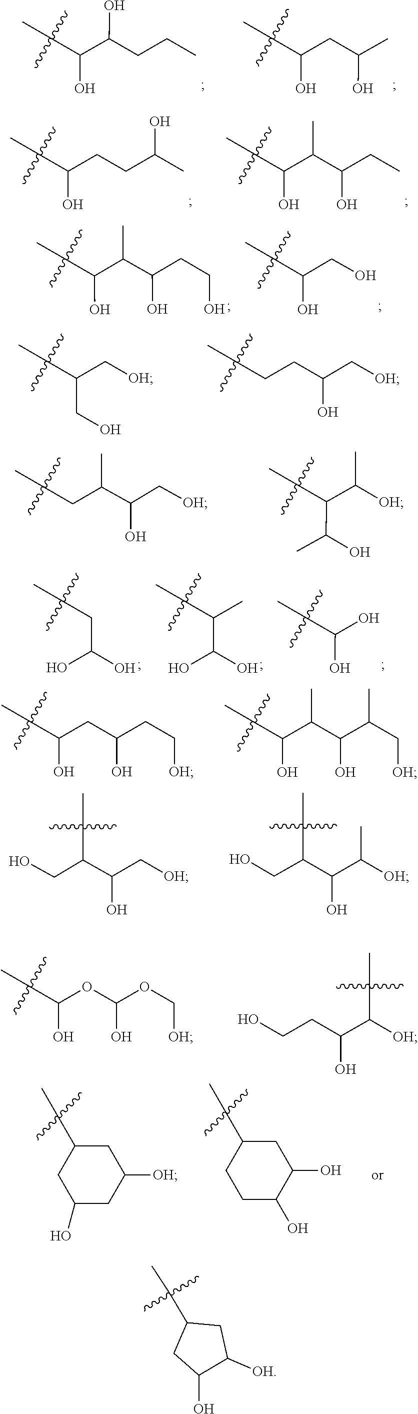

7. The photoresist stack of claim 1, wherein R³ comprises an aliphatic group having a reactive group selected from an epoxy, hydroxide, azo, alkyl halide, imine, alkene, alkyne, peroxide or allene group.

8. The photoresist stack of claim 7, wherein R³ has one of the following structures: 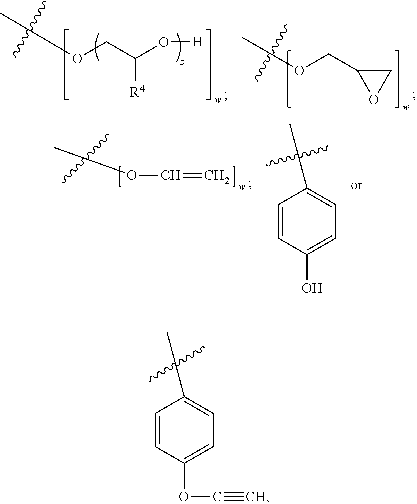
wherein:
R⁴ is, at each occurrence, H, alkyl, heteroalkyl, aryl or heteroaryl;
z is an integer of 1 to 300; and
w is an integer of 1 to 6.

9. The photoresist stack of claim 1, wherein L¹, L² and L³ are independently unsubstituted or halogen-substituted C₁-C₁₂ alkylene or C₂-C₁₂ alkylene interrupted by —S—, —P—, —P(O₂)—, —C(═O)S—, —C(═O)O—, —O—, —N—, —C(50 O)N—, —SO₂O—, —SO₂S—, —SO—, —SO₂—, —C₆H₆—O—, —C₆H₆—O—C(═O)O— or —C(═O)—.

10. The photoresist stack of claim 1, wherein p is 0 and the polymer of structure (I) has the following structure (IA):

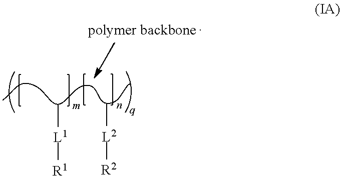

11. The photoresist stack of claim 10, wherein the polymer of structure (IA) has the following structure (IB): 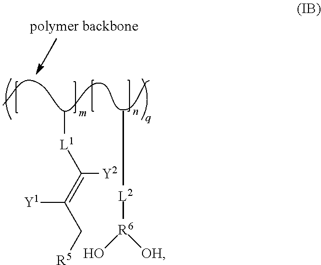
wherein:
Y¹ and Y² are, at each occurrence, independently OR^{a}, NR^{b}R^{c}, F, Cl, Br, or I;
R⁵ is, at each occurrence, H, OH, unsubstituted or halogen-substituted C₁-C₁₂ alkyl or C₂-C₁₂ heteroalkyl comprising at least one of —S—, —P—, —P(O₂)—, —C(═O)S—, —C(═O)O—, —O—, —N—, —C(═O)N—, —SO₂O—, —SO₂S—, —SO—, —SO₂—, —C₆H₆—O—, —C₆H₆—O—C(═)O— or —C(═O)—, or C₅-C₁₈ aryl;
R⁶ is, at each occurrence, C₁-C₁₂ alkylene or C₃-C₁₈ cycloalkylene; and
R^{a}, R^{b} and R^{c} are, at each occurrence, independently H or C₁-C₁₂ alkyl.

12. A photoresist stack for lithography patterning, comprising:
a coating layer over a substrate, wherein the coating layer is derived from a coating composition comprising a polymer having the following structure (II): 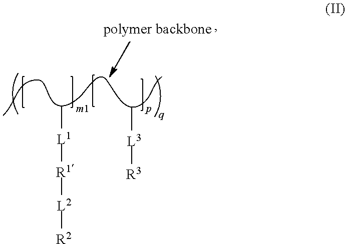
wherein:
L¹, L² and L³ are, at each occurrence, independently an optional alkylene, alkenylene, alkynylene, heteroalkylene, heteroalkenylene, heteroalkynylene, cycloalkylene, heterocycloalkylene, arylene or heteroarylene linker;
R^{1′} is, at each occurrence, a hydrogen donor group capable of generating a hydrogen radical upon exposure to actinic radiation or heat;
R² is, at each occurrence, a water donor group capable of producing water upon exposure to actinic radiation or heat;
R³ is, at each occurrence, a crosslinking group;
m1 and q are independently an integer of one or greater; and
p is an integer of zero or greater; and
a photoresist layer over the coating layer, the photoresist layer comprising an organometallic compound.

13. The photoresist stack of claim 12, wherein R^{1′} is an alkylene, alkenylene, heteroalkylene, cycloalkylene, heterocycloalkylene, arylene, or heteroarylene group comprising a cleavable C—H bond.

14. The photoresist stack of claim 13, wherein R^{1′} has the following structure: 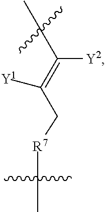
wherein:
Y¹ and Y² are, at each occurrence, independently OR^{a}, NR^{b}R^{c}, F, Cl, Br or I;
R⁷ is, at each occurrence, C₁-C₁₂ alkylene or C₃-C₁₈ cycloalkylene; and
R^{a}, R^{b} and R^{c} are, at each occurrence, independently H or C₁-C₁₂ alkyl.

15. The photoresist stack of claim 12, wherein R² has one of the following structures:

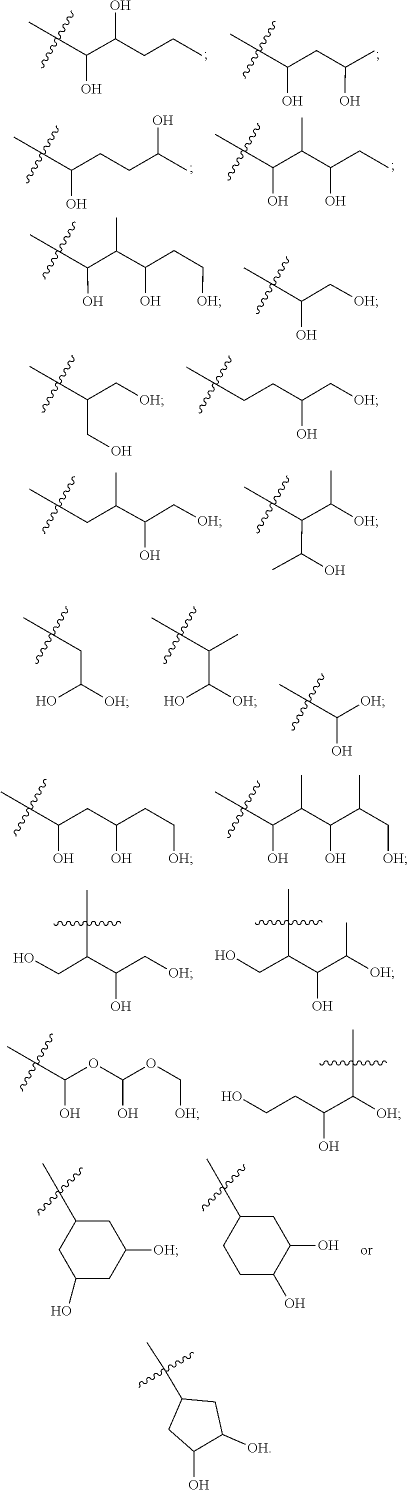

16. The photoresist stack of claim 12, wherein R³ has one of the following structures: 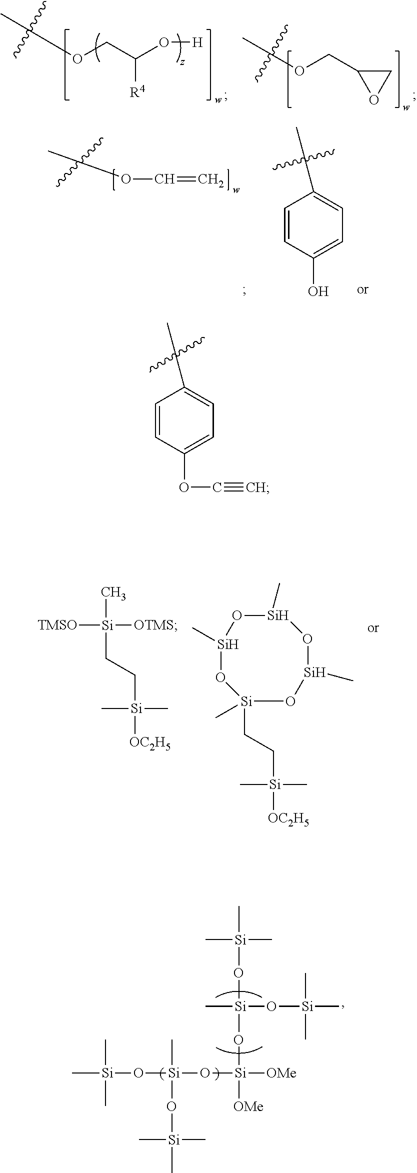
wherein:
R⁴ is, at each occurrence, H, alkyl, heteroalkyl, aryl or heteroaryl;
z is an integer of 1 to 300; and
w is an integer of 1 to 6.

17. A photoresist stack for lithography patterning, comprising:
a first material layer over a substrate;
a second material layer over the first material layer, wherein the second material layer is derived from a composition comprising a first polymer, a second polymer, and an acid generator, and
a photoresist layer over the second material layer,
wherein the first polymer has the following structure (III): 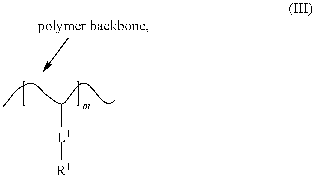
wherein:
L¹ is, at each occurrence, independently an optional alkylene, alkenylene, alkynylene, heteroalkylene, heteroalkenylene, heteroalkynylene, cycloalkylene, heterocycloalkylene, arylene or heteroarylene linker;
R¹ is, at each occurrence, a hydrogen donor group capable of generating a hydrogen radical upon exposure to actinic radiation or heat; and
m is an integer of one or greater, and
wherein the second polymer has the following structure (IV): 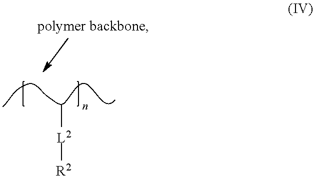
wherein:
L² is, at each occurrence, independently an optional alkylene, alkenylene, alkynylene, heteroalkylene, heteroalkenylene, heteroalkynylene, cycloalkylene, heterocycloalkylene, arylene or heteroarylene linker;
R² is, at each occurrence, a water donor group capable of producing water upon exposure to actinic radiation or heat; and
n is an integer of one or greater.

18. The photoresist stack of claim 17, wherein R¹is an alkyl, alkenyl, heteroalkyl, cycloalkyl, heterocycloalkyl, aryl or heteroaryl group.

19. The photoresist stack of claim 17, wherein R² is an aliphatic polyol having 20 or fewer carbon atoms, an alkyl, cycloalkyl or heteroalkyl diol or an alkyl, cycloalkyl or heteroalkyl triol.

20. The photoresist stack of claim 17, the composition further comprising a third polymer having the following structure (V): 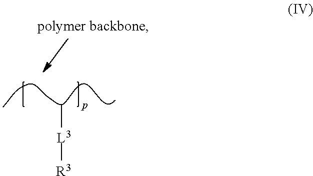
wherein:
L³ is, at each occurrence, independently an optional alkylene, alkenylene, alkynylene, heteroalkylene, heteroalkenylene, heteroalkynylene, cycloalkylene, heterocycloalkylene, arylene or heteroarylene linker,
R³ is, at each occurrence, a crosslinking group; and
p is an integer of one or greater.
